(19) United States
(12) Patent Application Publication
(10) Pub. No.: US 2026/0026088 A1
(43) Pub. Date: Jan. 22, 2026

(54) AREA SCALING USING AN EXTENDED FULL CUT WITH A SUPPORTING BACKSIDE GATE JUMPER

(71) Applicant: QUALCOMM Incorporated, San Diego, CA (US)

(72) Inventors: Shreesh NARASIMHA, Charlotte, NC (US); Yan SUN, San Diego, CA (US)

(21) Appl. No.: 18/774,146

(22) Filed: Jul. 16, 2024

(51) Int. Cl. H01L 27/088; H01L 21/762; H01L 21/8234; H01L 23/528; H01L 29/06; H01L 29/423; H01L 29/775; H01L 29/786

(52) U.S. Cl. CPC H10D 84/83; H01L 21/76224; H01L 23/5283; H10D 84/0151; H10D 84/038; H10D 30/43; H10D 30/6735; H10D 30/6757; H10D 62/121

(57) ABSTRACT

A chip includes one or more first channels extending in a first direction, a first epitaxial (epi) layer coupled to the one or more first channels, a first gate, wherein the one or more first channels pass through the first gate, one or more second channels extending in the first direction, a second epi layer coupled to the one or more second channels, and a second gate, wherein the one or more second channels pass through the second gate. The chip also includes a dielectric wall extending in the first direction, wherein the dielectric wall is disposed between the first epi layer and the second epi layer, and the dielectric wall is disposed between the first gate and the second gate. The chip further includes a backside bridge underneath the first gate and the second gate, wherein the backside bridge couples the first gate and the second gate.

### BACKGROUND

### Field

Aspects of the present disclosure relate generally to chip layout, and more particularly, to area scaling using an extended full cut with a supporting backside gate jumper.

### Background

A chip includes many transistors for performing various functions on the chip. The transistors may be implemented using gate-all-around field effect transistors (GAAFETs), fin field effect transistors (FinFETs), and/or other types of transistors. With advances in semiconductor technology, there is a continuous demand to scale down the dimensions of the transistors and the spacing between the transistors to fit a larger number of transistors on the chip.

### SUMMARY

The following presents a simplified summary of one or more implementations in order to provide a basic understanding of such implementations. This summary is not an extensive overview of all contemplated implementations and is intended to neither identify key or critical elements of all implementations nor delineate the scope of any or all implementations. Its sole purpose is to present some concepts of one or more implementations in a simplified form as a prelude to the more detailed description that is presented later.

A first aspect relates to a chip. The chip includes one or more first channels extending in a first direction, a first epitaxial (epi) layer coupled to the one or more first channels, a first gate, wherein the one or more first channels pass through the first gate, one or more second channels extending in the first direction, a second epi layer coupled to the one or more second channels, and a second gate, wherein the one or more second channels pass through the second gate. The chip also includes a dielectric wall extending in the first direction, wherein the dielectric wall is disposed between the first epi layer and the second epi layer, and the dielectric wall is disposed between the first gate and the second gate. The chip further includes a backside bridge underneath the first gate and the second gate, wherein the backside bridge couples the first gate and the second gate.

A second aspect relates to a method of chip fabrication. The method includes etching through a gate and an interlayer dielectric (ILD) between a first epitaxial (epi) layer and a second epi layer to form a trench, wherein the etching cuts the gate into a first gate and a second gate. The method also includes filling the trench with a dielectric material to form a dielectric wall, and forming a backside bridge underneath the first gate and the second gate, the backside bridge coupling the first gate and the second gate.

A third aspect relates to a chip. The chip includes one or more first channels extending in a first direction, a first epitaxial (epi) layer coupled to the one or more first channels, one or more second channels extending in the first direction, and a second epi layer coupled to the one or more second channels. The chip also includes a gate extending in a second direction perpendicular to the first direction, wherein the one or more first channels and the one or more second channels pass through the gate. The chip also includes a dielectric wall extending in the first direction, wherein the dielectric wall is disposed between the first epi layer and the second epi layer, the dielectric wall is disposed between a first portion of the gate and a second portion of the gate, and a third portion of the gate passes over the dielectric wall. The chip also includes a backside bridge extending in the second direction underneath the first portion of the gate, the second portion of the gate, and the dielectric wall, wherein the backside bridge is coupled between the first portion of the gate and the second portion of the gate.

### BRIEF DESCRIPTION OF THE DRAWINGS

FIG. 1A shows a side view of an example of a chip including a transistor and multiple topside layers according to certain aspects of the present disclosure.

FIG. 1B shows a perspective view of the transistor implemented with a gate-all-around FET according to certain aspects of the present disclosure.

FIG. 1C shows a perspective view of the transistor implemented with a finFET according to certain aspects of the present disclosure.

FIG. 1D shows a side view of the chip of FIG. 1A further including multiple backside layers according to certain aspects of the present disclosure.

FIG. 1E shows a side view of the chip of FIG. 1D further including a via disposed between a backside contact and a backside metal layer according to certain aspects of the present disclosure.

FIG. 2A shows a top view of an example of a cell including a first transistor and a second transistor according to certain aspects of the present disclosure.

FIG. 2B shows a top view of an example of backside rails extending underneath the transistors of FIG. 2A according to certain aspects of the present disclosure.

FIG. 2C shows a cross-sectional view of a first epitaxial (epi) layer and a second epi layer of the transistors of FIG. 2A according to certain aspects of the present disclosure.

FIG. 2D shows a cross-sectional view of a shared gate and channels of the transistors of FIG. 2A according to certain aspects of the present disclosure.

FIG. 3 shows an example in which spacings between epi layers of FIG. 2A are reduced according to certain aspects of the present disclosure.

FIG. 4A shows a top view of dielectric walls that extend between epi layers and gates according to certain aspects of the present disclosure.

FIG. 4B shows a cross-sectional view of the dielectric walls and the epi layers of FIG. 4A according to certain aspects of the present disclosure.

FIG. 4C shows a cross-sectional view of the dielectric walls and the gates of FIG. 4A according to certain aspects of the present disclosure.

FIG. 5A shows a cross-sectional view of epi layers formed on a semiconductor substrate according to certain aspects of the present disclosure.

FIG. 5B shows a cross-sectional view of a gate and channels passing through the gate according to certain aspects of the present disclosure.

FIG. 5C shows a cross-sectional view in which trenches are etched between the epi layers according to certain aspects of the present disclosure.

FIG. 5D shows a cross-sectional view in which the trenches cut through the gate of FIG. 5B according to certain aspects of the present disclosure.

FIG. 5E shows a cross-sectional view in which the trenches are filled with dielectric material to form dielectric walls according to certain aspects of the present disclosure.

FIG. 5F shows a cross-sectional view of the dielectric walls after most or all of the semiconductor substrate has been removed according to certain aspects of the present disclosure.

FIG. 6A shows a top view of an example of signal routing for a cell according to certain aspects of the present disclosure.

FIG. 6B shows a cross-sectional view of the cell taken along a first cross-section line in FIG. 6A according to certain aspects of the present disclosure.

FIG. 6C shows a cross-sectional view of the cell taken along a second cross-section line in FIG. 6A according to certain aspects of the present disclosure.

FIG. 6D shows a cross-sectional view of the cell taken along a third cross-section line in FIG. 6A according to certain aspects of the present disclosure.

FIG. 7 is a flowchart illustrating a method of chip fabrication according to certain aspects of the present disclosure.

FIG. 8A shows a top view of an example of a dielectric wall that extends between epi layers and passes through a gate according to certain aspects of the present disclosure.

FIG. 8B shows a cross-sectional view of the dielectric wall and the epi layers of FIG. 8A according to certain aspects of the present disclosure.

FIG. 8C shows a cross-sectional view of the dielectric wall and the gate of FIG. 8A according to certain aspects of the present disclosure.

### DETAILED DESCRIPTION

The detailed description set forth below, in connection with the appended drawings, is intended as a description of various configurations and is not intended to represent the only configurations in which the concepts described herein may be practiced. The detailed description includes specific details for the purpose of providing a thorough understanding of the various concepts. However, it will be apparent to those skilled in the art that these concepts may be practiced without these specific details. In some instances, well-known structures and components are shown in block diagram form in order to avoid obscuring such concepts.

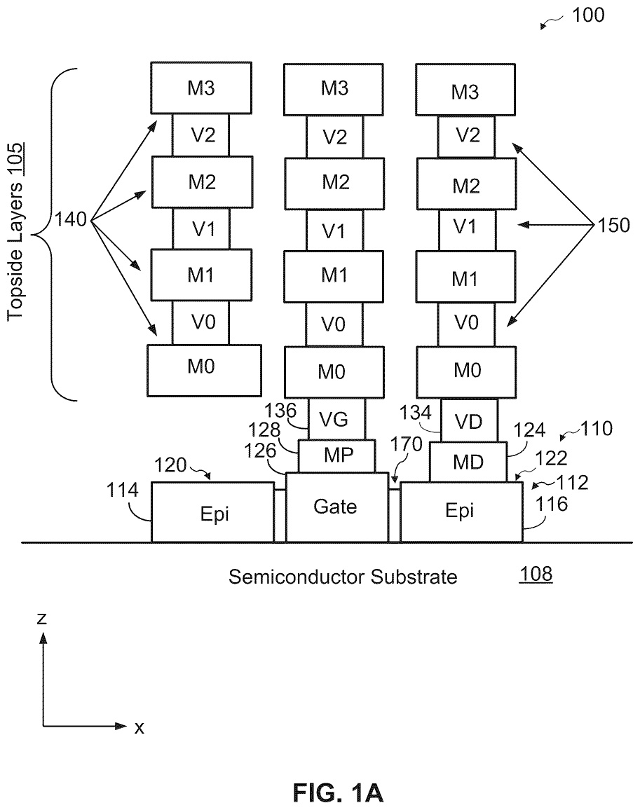

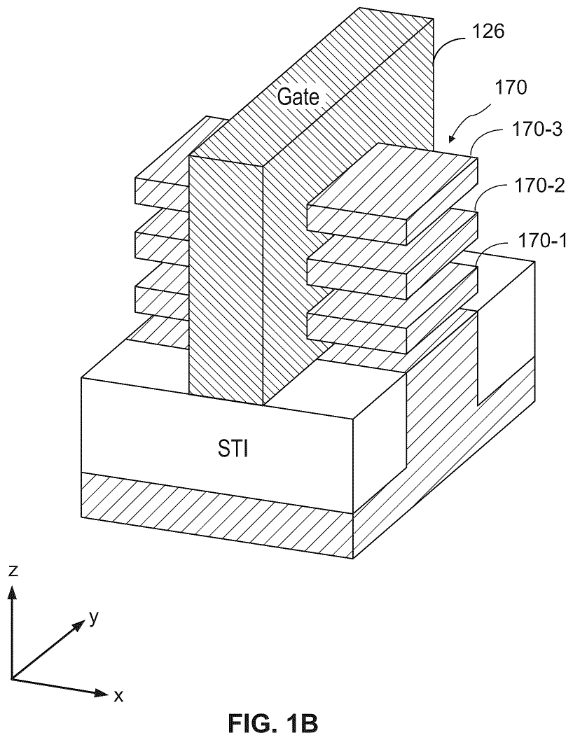

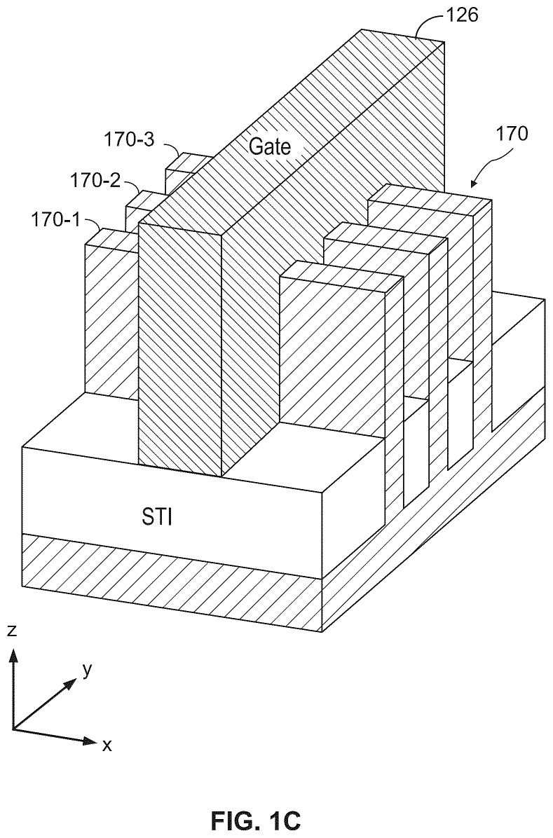

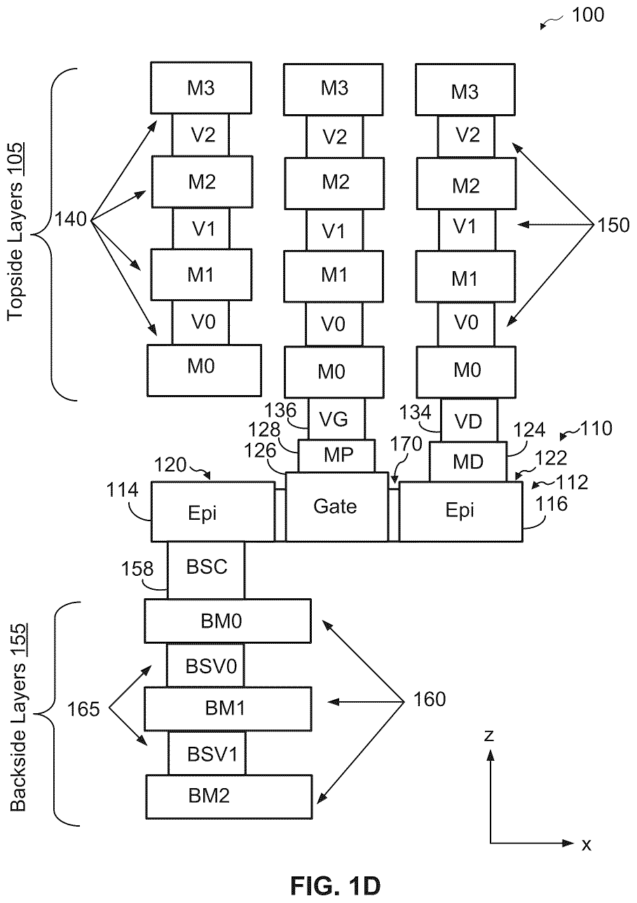

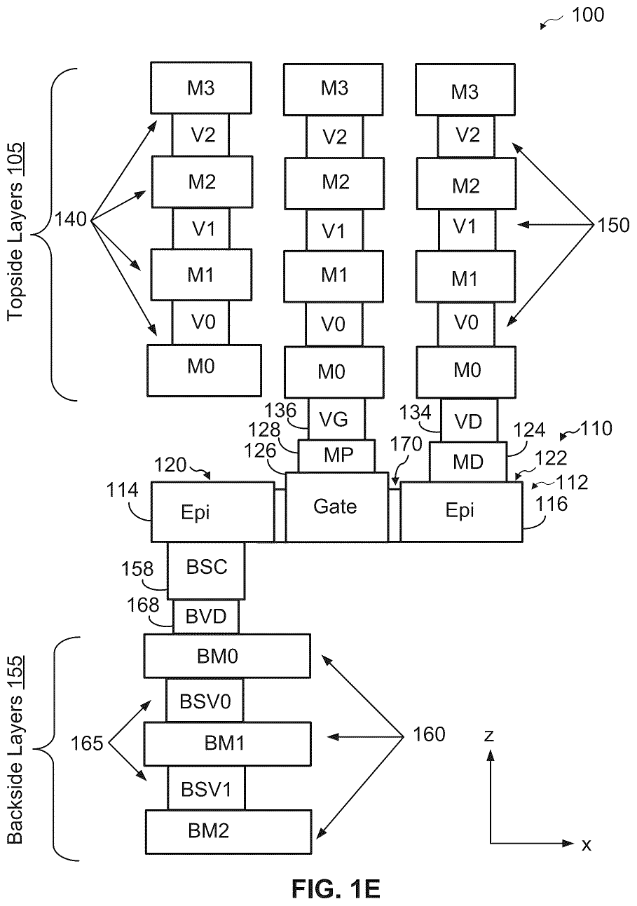

FIG. 1A shows a side view of an example of a chip 100 (e.g., a die) including a transistor 110 and multiple topside layers 105 (also referred to as frontside layers) according to certain aspects. Although one transistor 110 is shown in FIG. 1A for simplicity, it is to be appreciated that the chip 100 includes many transistors. As discussed further below, the transistor 110 may be implemented using a gate-all-around field effect transistor (FET) process, a fin field-effect transistor (FinFET) process, or another type of process. The topside layers 105 are above the transistor 110 in the z direction shown in FIG. 1A. The transistor 110 and the topside layers 105 may be formed on a semiconductor substrate 108 (e.g., silicon substrate).

In the example shown in FIG. 1A, the transistor 110 includes a diffusion region 112 and a gate 126 on the diffusion region 112. The diffusion region 112 may also be referred to as an oxide diffusion region, an active region, active diffusion, active (RX), or another term. The gate 126 may be formed on the diffusion region 112, and may include a gate metal (e.g., a high-k metal gate (HKMG)), polysilicon, and/or another gate material. The diffusion region 112 includes one or more channels 170 extending in the x direction in FIG. 1A, where the x direction is perpendicular to the z direction. As used herein, a “channel” is a structure that conducts current between a source and a drain of a transistor. For a gate-all-around FET process, the diffusion region 112 may correspond to an area of the chip 100 where one or more nanosheets are formed, in which the gate 126 is formed around a portion of the one or more nanosheets to provide the one or more channels 170. In this example, portions of the one or more nanosheets outside of the gate 126 may be cut and epi layers may be coupled to opposite sides of the one or more channels 170, as discussed further below.

For the example of a gate-all-around FET process, the gate 126 may surround each of the one or more channels 170 (also referred to as ribbons) on four sides. In this regard, FIG. 1B shows a perspective view in which the one or more channels 170 include channels 170-1, 170-2, and 170-3 where each of the channels 170-1, 170-2, and 170-3 is surrounded on four sides by the gate 126. Each of the channels 170-1, 170-2, and 170-3 may include a nanosheet, a nanowire, or the like. In this example, the channels 170-1, 170-2, and 170-3 are stacked vertically and are spaced apart from one another in the z direction. However, it is to be appreciated that the present disclosure is not limited to this example. In certain aspects, the chip 100 may include shallow trench isolation (STI) to reduce leakage between devices on the chip 100. In some implementations, the STI may be omitted.

For the example of a finFET process, the gate 126 may surround each of the one or more channels 170 on three sides. In this regard, FIG. 1C shows a perspective view in which the one or more channels 170 include channels 170-1, 170-2, and 170-3 where each of the channels 170-1, 170-2, and 170-3 is surrounded on three sides by the gate 126. In this example, each of the channels 170-1, 170-2, and 170-3 is orientated vertically, and the channels 170-1, 170-2, and 170-3 are spaced apart from one another in the y direction. The channels for a finFET process may also be referred to as fins.

Returning to FIG. 1A, the transistor 110 may include a first epitaxial (epi) layer 114 and a second epi layer 116 in which the gate 126 is disposed between the first epi layer 114 and the second epi layer 116. The first epi layer 114 is coupled to the one or more channels 170 on one side of the gate 126 to provide a first source/drain 120. The second epi layer 116 is coupled to the one or more channels 170 on the other side of the gate 126 to provide a second source/drain 122. An epi layer may also be referred to as simply epi or another term. As used herein, the term “source/drain” means a source, a drain, or both a source and a drain.

As shown in FIG. 1A, the first epi layer 114 and the second epi layer 116 are located on opposite sides of the gate 126. Each of the first epi layer 114 and the second epi layer 116 may include epitaxially grown or deposited silicon, a silicon-based material (e.g., silicon-germanium), or any combination thereof. In this example, the gate 126 controls the conductivity between the first source/drain 120 and the second source/drain 122 based on a voltage applied to the gate 126. The transistor 110 may include a first spacer (not shown) between the gate 126 and the first epi layer 114 and a second spacer (not shown) between the gate 126 and the second epi layer 116, in which the one or more channels 170 pass through the first and second spacers.

In this example, the chip 100 includes a topside contact 124 formed on a top surface of the second source/drain 122. A top surface may also be referred to as a frontside surface. The contact 124 may be formed (i.e., patterned) from a topside contact layer using, for example, lithographic and etching processes. The contact 124 may be referred to as a metal-diffusion (MD) contact, contact active (CA), or another term. The chip 100 may also include a gate contact 128 formed on the gate 126. The gate contact 128 may be referred to as a metal-poly (MP) contact or another term. The gate contact 128 may be omitted in some implementations. A topside contact may also be referred to as a frontside contact or another term.

In this example, the topside layers 105 include topside metal layers 140. A topside metal layer may also be referred to as a frontside metal layer, a metal interconnect, or another term. The topside metal layers 140 may be patterned (e.g., using lithography and etching) to provide signal routing for the transistor 110 and other transistors (not shown in FIG. 1A) integrated on the chip 100. In some implementations, the topside metal layers 140 may also be patterned to form a power distribution network including supply rails for distributing power to the transistor 110 and other transistors integrated on the chip 100. In other implementations, the power distribution network is provided using backside layers (e.g., to reduce routing congestion in the topside layers 105), as discussed further below with reference to FIG. 1D.

In the example in FIG. 1A, the bottom-most topside metal layer among the topside metal layers 140 is referred to as metal layer M0. The topside metal layer immediately above metal layer M0 is referred to as metal layer M1, the topside metal layer immediately above metal layer M1 is referred to as metal layer M2, the topside metal layer immediately above metal layer M2 is referred to as metal layer M3, and so forth. Although four topside metal layers 140 (i.e., M0 to M3) are shown in FIG. 1A for ease of illustration, it is to be appreciated that the topside layers 105 may include additional topside metal layers above metal layer M3. It is to be appreciated that the present disclosure is not limited to the nomenclature in which the bottom-most topside metal layer is referred to as metal layer M0. For instance, in another example, the bottom-most topside metal layer may be referred to as metal layer M1 instead of metal layer M0.

The topside layers 105 also includes vias 150 that provide coupling between the topside metal layers 140. In this example, the vias V0 provide coupling between metal layer M0 and metal layer M1, the vias V1 provide coupling between metal layer M1 and metal layer M2, and the vias V2 provide coupling between metal layer M2 and metal layer M3. In the example in FIG. 1A, the chip also includes a via 136 disposed between the gate contact 128 and metal layer M0, in which the via 136 couples the gate contact 128 (and hence the gate 126) to metal layer M0. For implementations where the gate contact 128 is omitted, the via 136 may be disposed between the gate 126 and metal layer M0 without an intervening gate contact. Also, in this example, the chip 100 includes a via 134 disposed between the contact 124 and metal layer M0, in which the via 134 couples the contact 124 to metal layer M0. In some implementations, the via 134 may be omitted with the contact 124 directly contacting metal layer M0.

In certain aspects, most or all of the semiconductor substrate 108 is removed to form backside layers under the transistors (e.g., transistor 110) on the chip 100. As used herein, “most” of the semiconductor substrate 108 means at least 90 percent of the semiconductor substrate 108. For example, after formation of the transistors and the topside layers 105, a carrier wafer (not shown) may be bonded to the top of the chip 100 for structural support. The chip 100 may then be flipped to expose the backside of the semiconductor substrate 108, and most or all of the semiconductor substrate 108 may be grounded and/or polished off (e.g., using chemical mechanical polishing (CMP)). Backside layers may then be formed under the transistors on the chip 100.

In this regard, FIG. 1D shows an example of backside layers 155 formed under the transistor 110. In this example, the backside layers 155 include backside metal layers 160. The backside metal layers 160 may be patterned (e.g., using lithography and etching) to form a power distribution network including supply rails for distributing power to the transistor 110 and other transistors on the chip 100.

In the example in FIG. 1D, the top-most backside metal layer among the backside metal layers 160 is referred to as backside metal layer BM0. The backside metal layer immediately below backside metal layer BM0 is referred to as backside metal layer BM1, the backside metal layer immediately below backside metal layer BM1 is referred to as backside metal layer BM2, and so forth. Although three backside metal layers 160 (i.e., BM0 to BM2) are shown in FIG. 1D for ease of illustration, it is to be appreciated that the backside layers 155 may include additional metal layers below backside metal layer BM2.

In the example in FIG. 1D, the chip 100 includes a backside contact 158 formed on a bottom surface (i.e., backside surface) of the first source/drain 120. The backside contact 158 may be formed (i.e., patterned) from a backside contact layer (labeled “BSC”) using, for example, lithographic and etching processes. The backside contact 158 is used to couple the first source/drain 120 to backside metal layer BM0. In some implementations, the backside contact 158 may directly contact backside metal layer BM0, as shown in the example in FIG. 1D. In other implementations, the backside contact 158 may be coupled to backside metal layer BM0 through an intervening via. In this regard, FIG. 1E shows an example in which the chip 100 includes a backside via 168 (labeled “BVD”) disposed between the backside contact 158 and backside metal layer BM0. In this example, the backside via 168 provides a space between the backside contact 158 and backside metal layer BM0 in the z direction.

In the examples in FIG. 1D and FIG. 1E, the backside layers 155 include vias 165 that provide coupling between the backside metal layers 160. In this example, the vias 165 include a via BSV0 that provides coupling between backside metal layer BM0 and backside metal layer BM1, and a via BSV1 that provides coupling between backside metal layer BM1 and backside metal layer BM2.

In certain aspects, the topside metal layers 140 are patterned (e.g., using lithography and etching) to provide signal routing for the transistor 110 and other transistors (not shown in FIG. 1A) integrated on the chip 100, and the backside metal layers 160 are patterned to form a power distribution network including supply rails for distributing power to the transistor 110 and the other transistors integrated on the chip 100. Moving the power distribution network to the backside layers 155 helps reduce routing congestion compared with the case in which the topside layers 105 are used for both signal routing and power distribution. It is to be appreciated that, in some implementations, both the topside metal layers 140 and the backside metal layers 160 may be used for signal routing.

Although one gate 126 is shown in FIGS. 1A to IE, it is to be appreciated that the transistor 110 may include multiple gates arranged in parallel and coupled to one another (e.g., through metal layer M0 or another metal layer). A transistor with multiple gates may be referred to as a multi-gate transistor, a multi-finger transistor, or another term.

Transistors on the chip 100 may be organized into cells. Each cell may include one or more transistors that are arranged to provide a circuit (e.g., an inverter, a driver, a logic gate, combinational logic, a latch, a flip-flop, a bit cell (e.g., a static random-access memory (SRAM) bit cell), or another type of circuit. The layout of each cell may be specified (i.e., defined) in a standard cell library, which may be stored in a memory. The standard cell library may specify (i.e., define) the layout of each one of various cells that can be placed (i.e., laid out) on the chip 100 for a particular process. The chip 100 may include multiple instances of a particular cell defined in the standard cell library. The layout of each cell defined in the standard cell library may include the layout of gates, diffusion regions, and contacts in the cell.

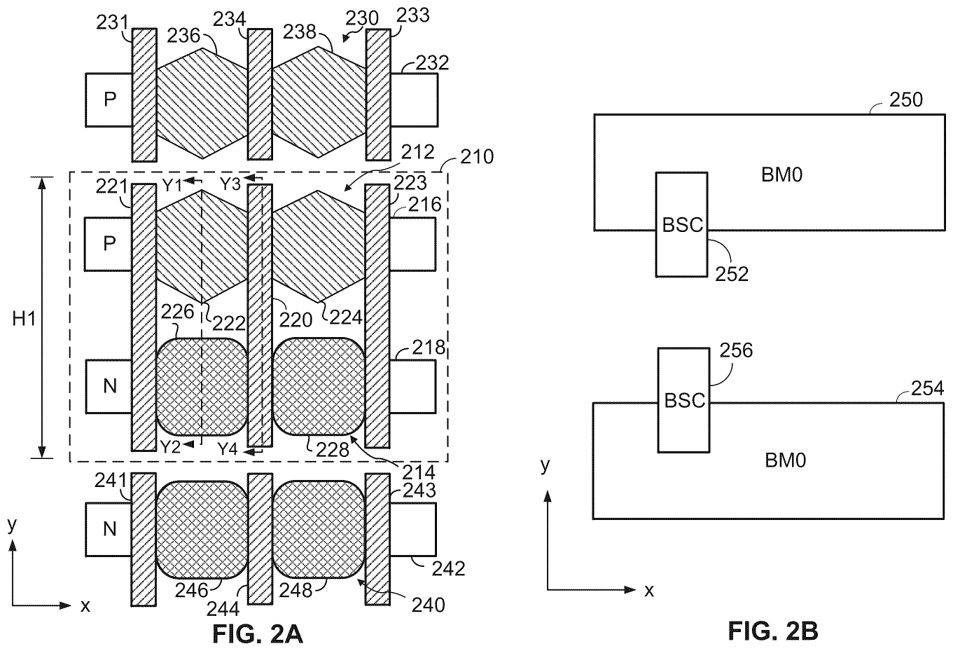

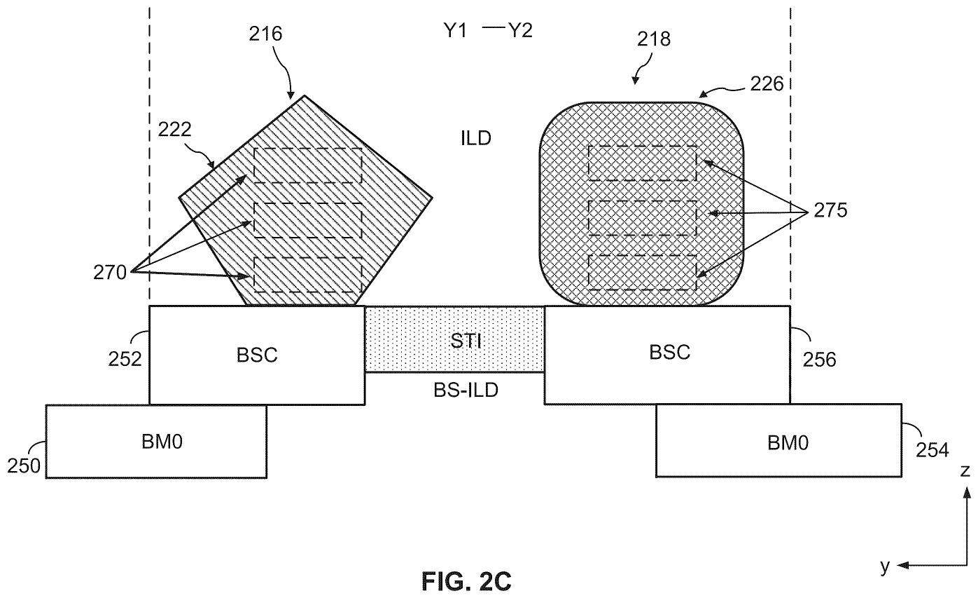

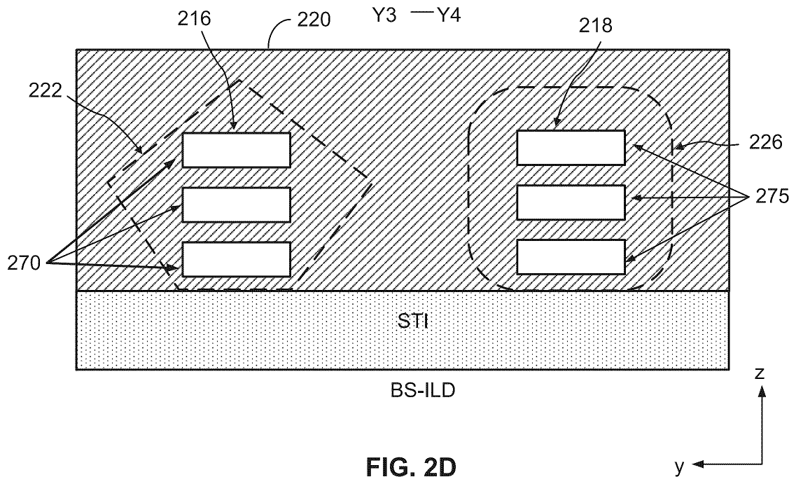

FIG. 2A shows a top view of an exemplary cell 210 integrated on the chip 100 according to certain aspects. In this example, the cell 210 includes a first diffusion region 216 extending in the x direction and a second diffusion region 218 extending in the x direction, in which the first diffusion region 216 and the second diffusion region 218 are spaced apart in the y direction, which is perpendicular to the x direction and the z direction. Each of the diffusion regions 216 and 218 may include one or more respective channels (e.g., a respective instance of the one or more channels 170) extending in the x direction. In this example, the first diffusion region 216 may be a p-type diffusion region and the second diffusion region 218 may be an n-type diffusion region (e.g., to provide the cell 210 with complementary transistors). However, it is to be appreciated that the present disclosure is not limited to this example. It is also to be appreciated that the cell 210 may include more than two diffusion regions in other implementations.

The cell 210 includes a gate 220 extending in the y direction over the first diffusion region 216 and the second diffusion region 218. The gate 220 may include a metal (e.g., a high-k metal gate (HKMG)), polysilicon, and/or another gate material. For a gate-all-around FET process, the gate 126 may surround each of the one or more channels of the first diffusion region 216 on four sides, and surround each of the one or more channels of the second diffusion region 218 on four sides (e.g., as illustrated in the example in FIG. 1B). For a finFET process, the gate 126 may surround each of the one or more channels of the first diffusion region 216 on three sides, and surround each of the one or more channels of the second diffusion region 218 on three sides (e.g., as illustrated in the example in FIG. 1C).

The first diffusion region 216 includes epitaxial (epi) layer 222, one or more channels 270 (shown in FIG. 2D), and epi layer 224. The second diffusion region 218 includes epi layer 226, one or more channels 275 (shown in FIG. 2D), and epi layer 228. In the discussion below, the epi layer 222 is referred to as the first epi layer 222, the epi layer 226 is referred to as the second epi layer 226, the epi layer 224 is referred to as the third epi layer 224, and the epi layer 228 is referred to as the fourth epi layer 228. Each of the first epi layer 222, the second epi layer 226, the third epi layer 224, and the fourth epi layer 228 may include epitaxially grown or deposited silicon, a silicon-based material (e.g., silicon-germanium), or any combination thereof. The gate 220 is disposed between the first epi layer 222 and the third epi layer 224, in which the one or more channels 270 (shown in FIG. 2D) pass through the gate 220 and are coupled between the first epi layer 222 and the third epi layer 224. The gate 220 is also disposed between the second epi layer 226 and the fourth epi layer 228, in which the one or more channels 275 (shown in FIG. 2D) pass through the gate 220 and are coupled between the second epi layer 226 and the fourth epi layer 228. The first epi layer 222 and the second epi layer 226 are spaced apart in the y direction, and the third epi layer 224 and the fourth epi layer 228 are spaced apart in the y direction, as shown in FIG. 2A.

In this example, the first diffusion region 216 and the gate 220 form a first transistor 212 (e.g., a p-type field effect transistor (PFET)), in which the first epi layer 222 provides a first source/drain and the third epi layer 224 provides a second source/drain of the first transistor 212. The second diffusion region 218 and the gate 220 form a second transistor 214 (e.g., an n-type field effect transistor (NFET)), in which the second epi layer 226 provides a first source/drain and the fourth epi layer 228 provides a second source/drain for the second transistor 214.

In this example, the first transistor 212 and the second transistor 214 share the gate 220. In other words, the gate 220 is common to both the first transistor 212 and the second transistor 214. Two or more transistors may share a common gate in various types of cells. For example, complementary transistors (e.g., a PFET and an NFET) may share a common gate in an inverter cell, an SRAM cell, or another type of cell. For the example of an inverter cell, the common gate of the complementary transistors may be coupled to the input of the inverter cell. For the example of an SRAM cell, the common gate of the complementary transistors (e.g., a pull-up (PU) transistor and a pull-down (PD) transistor) may be coupled to a source/drain of a pass-gate (PG) transistor in the SRAM cell.

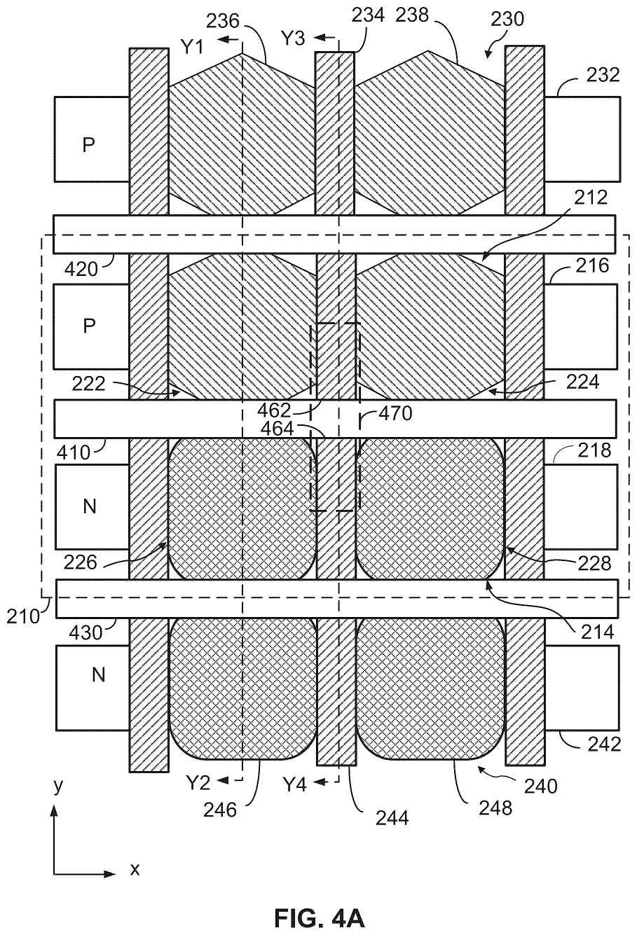

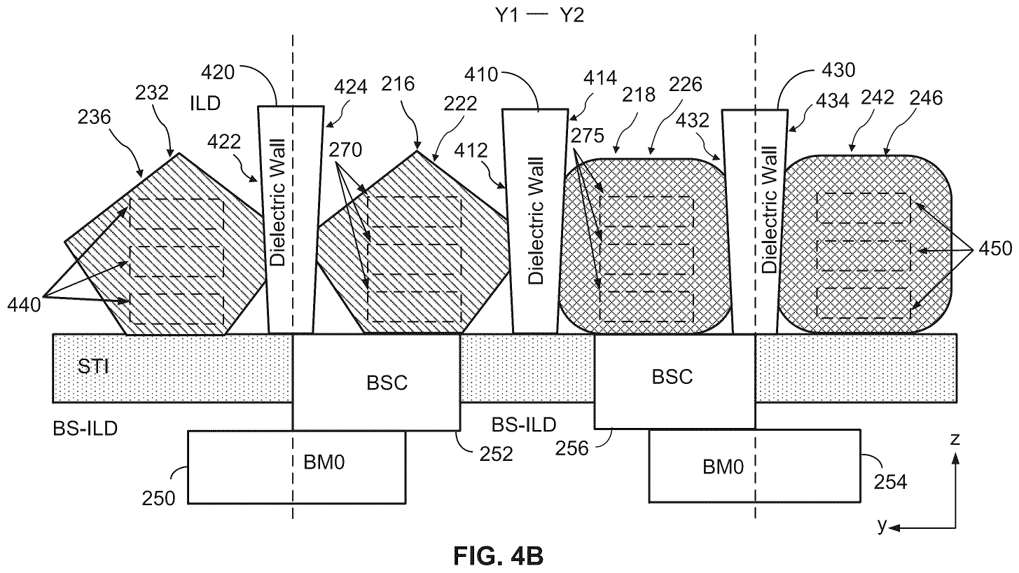

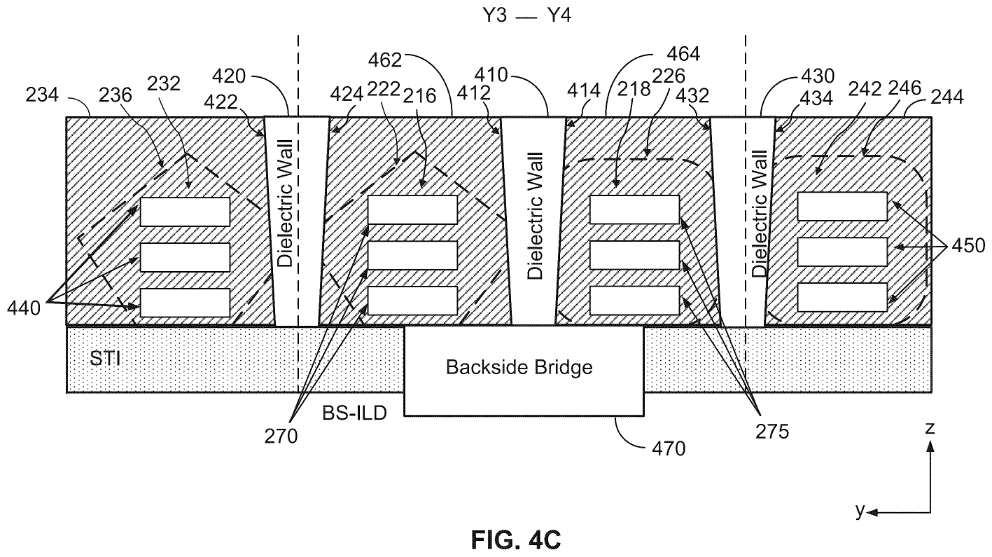

In this example, the chip 100 also includes a third diffusion region 232 extending in the x direction and a gate 234 extending in the y direction over the third diffusion region 232. The third diffusion region 232 includes a fifth epi layer 236, one or more channels 440 (shown in FIG. 4C), and a sixth epi layer 238. The gate 234 is disposed between the fifth epi layer 236 and the sixth epi layer 238, in which the one or more channels 440 pass through the gate 234 and are coupled between the fifth epi layer 236 and the sixth epi layer 238. In this example, the gate 234 and the third diffusion region 232 form a third transistor 230 (e.g., a PFET) located above the cell 210 in the y direction. The third transistor 230 may be part of a cell adjacent to the cell 210.

In this example, the chip 100 also includes a fourth diffusion region 242 extending in the x direction and a gate 244 extending in the y direction over the fourth diffusion region 242. The fourth diffusion region 242 includes a seventh epi layer 246, one or more channels 450 (shown in FIG. 4C), and an eighth epi layer 248. The gate 244 is disposed between the seventh epi layer 246 and the eighth epi layer 248, in which the one or more channels 450 pass through the gate 244 and are coupled between the seventh epi layer 246 and the eighth epi layer 248. In this example, the gate 244 and the fourth diffusion region 242 form a fourth transistor 240 (e.g., a NFET) located below the cell 210 in the y direction. The fourth transistor 240 may be part of a cell adjacent to the cell 210.

As shown in FIG. 2A, each epi layer extends laterally in the y direction. This is because the epitaxial process (e.g., epitaxial growth process) for each epi layer forms (e.g., grows) the epi layer in both the z and y directions. As discussed further below, the lateral growth of the epi layers in the y direction can potentially lead to shorts between adjacent epi layers.

In the example illustrated in FIG. 2A, the chip 100 includes additional gates 221, 223, 231, 233, 241, and 243 spaced apart from the gates 220, 234, and 244 in the x direction (e.g., at a uniform pitch). The additional gates 221, 223, 231, 233, 241, and 243 may be dummy gates (also known as non-functional gates). In other implementations, the transistors 212, 214, 230, and 240 may be multi-gate transistors, and the additional gates 221, 223, 231, 233, 241, and 243 may be additional gates of the transistors 212, 214, 230, and 240. In some implementations, the additional gates 221, 223, 231, 233, 241, and 243 may be replaced with diffusion breaks (e.g., single diffusion breaks).

Although not shown in FIG. 2A, it is to be appreciated that the gate 220 may be spaced apart from the epi layers 222, 224, 226, and 228 in the x direction by thin spacers (not shown), the gate 234 may be spaced apart from the epi layers 236 and 238 in the x direction by thin spacers (not shown), and the gate 244 may be spaced apart from the epi layers 246 and 248 in the x direction by thin spacers (not shown). A spacer may also be referred to as a sidewall spacer or another term. It is also to be appreciated that the chip 100 may include one or more additional epi layers (not shown). For example, the chip 100 may include one or more epi layers (not shown) to the left of the gate 221 and/or one or more epi layers (not shown) to the right of the gate 223.

Power may be distributed to the transistors 212, 214, 230, and 240 using backside layers (e.g., the backside layers 155). In this regard, FIG. 2B shows a top view of a first rail 250 and a second rail 254 formed from bottom metal layer BM0, which is below the transistors 212, 214, 230, and 240 shown in FIG. 2A.

In this example, the first rail 250 extends in the x direction under the first transistor 212 and the third transistor 230 shown in FIG. 2A. The first rail 250 is coupled to the backside of the first epi layer 222 through a first backside contact 252 disposed between the first epi layer 222 and the first rail 250. In this example, the first rail 250 may be a supply rail (also referred to as a power rail) for coupling a supply voltage to the first epi layer 222. In certain aspects, the first rail 250 may be shared by the first transistor 212 and the third transistor 230. In these aspects, the first rail 250 may also be coupled to the fifth epi layer 236 by another backside contact (not shown in FIG. 2B). In other implementations, the fifth epi layer 236 may be coupled to another rail (e.g., another supply rail) or not coupled to a rail.

In this example, the second rail 254 extends in the x direction under the second transistor 214 and the fourth transistor 240 shown in FIG. 2A. The second rail 254 is coupled to the backside of the second epi layer 226 through a second backside contact 256 disposed between the second epi layer 226 and the second rail 254. In this example, the second rail 254 may be a ground rail. In certain aspects, the second rail 254 may be shared by the second transistor 214 and the fourth transistor 240. In these aspects, the second rail 254 may also be coupled to the seventh epi layer 246 by another backside contact (not shown in FIG. 2B). In other implementations, the seventh epi layer 246 may be coupled to another rail (e.g., another ground rail) or not coupled to a rail.

It is to be appreciated that the present disclosure is not limited to the example shown in FIG. 2B. For example, in other implementations, the first rail 250 may be coupled to the third epi layer 224 by the first backside contact 252 and/or the second rail 254 may be coupled to the fourth epi layer 228 by the second backside contact 256. Although FIG. 2B shows an example where the first backside contact 252 and the second backside contact 256 are aligned in the x direction, it is to be appreciated that the first backside contact 252 and the second backside contact 256 may be spaced apart in the x direction in some implementations. In other words, the first backside contact 252 and the second backside contact 256 need not be aligned in the x direction.

In this example, the first transistor 212 and the second transistor 214 in the cell 210 may be coupled to form a complementary inverter. For example, input signal routing in metal layer M0 may be coupled to the shared gate 220 by a gate via (e.g., via 136) to provide the input of the inverter, and output signal routing in metal layer M0 may be coupled to the third epi layer 224 and the fourth epi layer 228 by a metal contact (e.g., contact 124) and a via (e.g., via 134) to provide the output of the inverter. However, it is to be appreciated that the cell 210 is not limited to an inverter.

FIG. 2C shows a cross-sectional view of the cell 210 taken along cross-section line Y1-Y2 in FIG. 2A, which intersects the first epi layer 222 and the second epi layer 226. In FIG. 2C, the vertical dashed lines indicate the boundary of the cell 210. In this example, the one or more channels 270 and the one or more channels 275 are formed using a gate-all-around FET process, but are not limited to this example. In this example, the first epi layer 222 is coupled to the one or more channels 270 passing through the gate 220, and the second epi layer 226 is coupled to the one or more channels 275 passing through the gate 220. Note that the gate 220, the one or more channels 270, and the one or more channels 275 are not intersected by the cross-section line Y1-Y2 in this example. In FIG. 2C, the one or more channels 270 are shown in dashed line to indicate the position of the one or more channels 270 in the z direction and the y direction, and the one or more channels 275 are shown in dashed line to indicate the position of the one or more channels 275 in the z direction and the y direction.

FIG. 2C shows an example in which the first epi layer 222 and the second epi layer 226 have different shapes. This may be due to, for example, the first epi layer 222 and the second epi layer 226 being formed using different epitaxial processes and/or materials. For example, the first epi layer 222 may include silicon-germanium (SiGe) and the second epi layer 226 may include silicon. However, it is to be appreciated that the present disclosure is not limited to this example. In other implementations, the first epi layer 222 and the second epi layer 226 may have substantially the same shape. Also, in other implementations, the first epi layer 222 may have a shape that is different from the exemplary shape shown in FIG. 2C and/or the second epi layer 226 may have a shape that is different from the exemplary shape shown in FIG. 2C. In other words, the first epi layer 222 and the second epi layer 226 are not limited to a particular shape.

In the example shown in FIG. 2C, the chip 100 may also include shallow trench isolation (STI) to provide additional isolation between transistors (e.g., the first transistor 212 and the second transistor 214) on the chip 100. However, it is to be appreciated that the STI may be omitted in some implementations. The chip 100 may also include an interlayer dielectric (ILD) between the epi layers 222 and 226, and a backside interlayer dielectric (BS-ILD) to provide isolation between rails and/or other structures formed in one or more of the backside metal layers (e.g., backside metal layer BM0).

FIG. 2D shows a cross-sectional view of the cell 210 taken along cross-section line Y3-Y4 in FIG. 2A. As shown in FIG. 2D, the one or more channels 270 pass through the gate 220 and the one or more channels 275 pass through the gate 220. In the example shown in FIG. 2D, each of the one or more channels 270 is surrounded by the gate 220 on four sides and each of the one or more channels 275 is surrounded by the gate 220 on four sides. However, it is to be appreciated that the present disclosure is not limited to this example. Note that the epi layers 222 and 226 are not intersected by the cross-section line Y3-Y4 in this example. In FIG. 2D, the first epi layer 222 is shown in dashed line to indicate the position of the first epi layer 222 in the z direction and the y direction, and the second epi layer 226 is shown in dashed line to indicate the position of the second epi layer 226 in the z direction and the y direction.

It is desirable to reduce the heights of cells on the chip 100 in the y direction in order to fit a larger number of cells on the chip 100. Two obstacles to scaling down (i.e., reducing) cell height in advanced semiconductor processes include: 1) metal layer M0 pitch/resistance, and 2) minimum epi-epi spacing to avoid potential epi-epi shorts (e.g., a short between the first epi layer 222 and the second epi layer 226). The first obstacle can be relieved by the backside power distribution discussed above, which reduces congestion in metal layer M0 by moving power distribution to the backside.

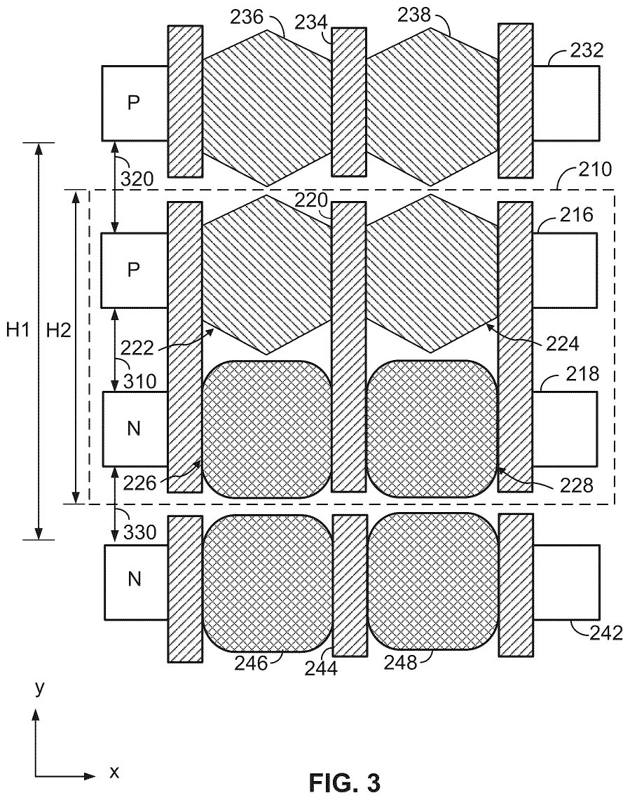

The second obstacle to scaling down cell height is illustrated in FIG. 3. In the example in FIG. 3, the spacing 310 between the first diffusion region 216 and the second diffusion region 218 in the cell 210 is reduced to reduce the height of the cell 210. Also, the spacing 320 between the first diffusion region 216 and the third diffusion region 232 is reduced, which reduces the height of the cell 210 by allowing the top boundary of the cell 210 to be moved closer to the first diffusion region 216. Further, the spacing 330 between the second diffusion region 218 and the fourth diffusion region 242 is reduced, which reduces the height of the cell 210 by allowing the bottom boundary of the cell 210 to be moved closer to the second diffusion region 218. In this example, the reduction in the spacings 310, 320, and 330 reduces the height of the cell 210 from H1 in FIG. 2A to H2 in FIG. 3. For comparison, both heights H1 and H2 are shown in FIG. 3.

However, reducing the spacings 310, 320, and 330 may significantly increase the risk of epi-epi shorts. For example, the widths of the epi layers in the y direction may vary due to process variation. As a result, the epi-epi spacing (i.e., spacing between adjacent epi layers) may need to be equal to or greater than a minimum spacing to ensure that process variation does not result in unintentional epi-epi shorts. The minimum spacing to avoid epi-epi shorts limits the ability to reduce the spacings 310, 320, and 330 to reduce the cell height.

To overcome the above limitations, aspects of the present disclosure provide a dielectric wall that electrically isolates adjacent epi layers, allowing the corresponding diffusion regions (i.e., active regions) to be spaced closer together to achieve cell height down scaling. In certain aspects, the dielectric wall also cuts a shared gate into a first gate and a second gate. In these aspects, a backside bridge (also referred to as a backside jumper) is coupled to a backside of the first gate and a backside of the second gate, and extends under the cut between the first gate and the second gate to provide electrical continuity between the first gate and the second gate. The formation of the backside bridge may be part of a backside contact process flow. The above features and other features of the present disclosure are discussed further below.

FIG. 4A shows a top view in which the chip 100 includes a first dielectric wall 410, a second dielectric wall 420, and a third dielectric wall 430 according to certain aspects. Each of the dielectric walls 410, 420, and 430 extends in the x direction, and the dielectric walls 410, 420, and 430 are spaced apart in the y direction. As used herein, a “dielectric wall” refers to a structure extending in the z direction and the x direction, and is made of substantially of one or more dielectric materials, such as silicon dioxide (SiO2), silicon nitride (Si3N4), silicon carbon oxynitride (SiCON), etc. A dielectric wall may also be referred to as a dielectric barrier, dielectric isolation, an epi-epi dielectric wall, an isolation structure, or another term. As discussed further below, each of the dielectric walls 410, 420, and 430 may be formed during frontside processing by etching a trench that extends in the x direction and the z direction and filling the trench with dielectric material.

In this example, the first dielectric wall 410 is disposed between the first epi layer 222 and the second epi layer 226. The first dielectric wall 410 is also disposed between the third epi layer 224 and the fourth epi layer 228. In this example, the first dielectric wall 410 cuts through the shared gate 220 in FIGS. 2A and 3, separating the shared gate 220 into a first gate 462 and a second gate 464. To retain electrical continuity between the first gate 462 and the second gate 464, the chip 100 includes a backside bridge 470 (shown in FIG. 4C) that electrically couples the first gate 462 and the second gate 464. The backside bridge 470 extends in the y direction underneath the first gate 462, the second gate 464, and the portion of the first dielectric wall 410 between the gates 462 and 464. The backside bridge 470 is shown in dashed line in FIG. 4A to indicate that the backside bridge 470 is underneath the first gate 462, the second gate 464, and the first dielectric wall 410. In this example, the backside bridge 470 is coupled to a backside of the first gate 462 and a backside of the second gate 464, and crosses under the first dielectric wall 410 to couple the first gate 462 and the second gate 464. The backside bridge may also be referred to as a backside gate jumper.

FIG. 4B shows a cross-sectional view taken along cross-section line Y1-Y2 in FIG. 4A, which intersects the first epi layer 222, the second epi layer 226, and the first dielectric wall 410. In FIG. 4B, the vertical dashed lines indicate the boundary of the cell 210. As shown in FIG. 4B, the first dielectric wall 410 is disposed between the first epi layer 222 and the second epi layer 226 to provide isolation between the first epi layer 222 and the second epi layer 226. The isolation prevents the first epi layer 222 and the second epi layer 226 from shorting, which allows the first diffusion region 216 and the second diffusion region 218 to be spaced closer together to scale down the height of the cell 210 without unintentionally shorting the first epi layer 222 and the second epi layer 226.

In this example, a first side 412 of the first dielectric wall 410 abuts the first epi layer 222 and a second side 414 of the first dielectric wall 410 abuts the second epi layer 226, in which the first side 412 and the second side 414 are opposite sides of the first dielectric wall 410. As shown in FIG. 4B, the first dielectric wall 410 extends in the z direction between the first epi layer 222 and the second epi layer 226. It is to be appreciated that the first dielectric wall 410 is not limited to the depth shown in the example in FIG. 4B. For example, the first dielectric wall 410 may extend further in the z direction in some implementations.

In the example shown in FIG. 4B, the one or more channels 270 are coupled to the first epi layer 222, and the one or more channels 275 are coupled to the second epi layer 226 discussed above with reference to FIG. 2C. However, it is to be appreciated that the present disclosure is not limited to this example.

Returning to FIG. 4A, the second dielectric wall 420 is disposed between the first epi layer 222 and the fifth epi layer 236. The second dielectric wall 420 is also disposed between the third epi layer 224 and the sixth epi layer 238. The second dielectric wall 420 also extends between the first gate 462 and the gate 234. In this case, a backside bridge is not used to couple the first gate 462 and the gate 234 since these gates are intended to be separate.

FIG. 4B shows a cross-sectional view taken along cross-section line Y1-Y2 in FIG. 4A, which intersects the first epi layer 222, the fifth epi layer 236, and the second dielectric wall 420. As shown in FIG. 4B, the second dielectric wall 420 is disposed between the first epi layer 222 and the fifth epi layer 236 to provide isolation between the first epi layer 222 and the fifth epi layer 236. The isolation prevents the first epi layer 222 and the fifth epi layer 236 from shorting, which allows the first diffusion region 216 and the third diffusion region 232 to be spaced closer together. The reduced spacing between the first diffusion region 216 and the third diffusion region 232 helps scale down the height of the cell 210 by allowing the top boundary of the cell 210 to be moved closer to the first diffusion region 216.

In this example, a first side 422 of the second dielectric wall 420 abuts the fifth epi layer 236 and a second side 424 of the second dielectric wall 420 abuts the first epi layer 222, in which the first side 422 and the second side 424 are opposite sides of the second dielectric wall 420. As shown in FIG. 4B, the second dielectric wall 420 extends in the z direction between the fifth epi layer 236 and the first epi layer 222. It is to be appreciated that the second dielectric wall 420 is not limited to the depth shown in the example in FIG. 4B.

In the example shown in FIG. 4B, the fifth epi layer 236 is coupled to the one or more channels 440 discussed above (shown in FIG. 4C). In FIG. 4B, the one or more channels 440 are shown in dashed line to indicate the position of the one or more channels 440 in the z direction and the y direction. Note that the cross-section line Y1-Y2 does not intersect the one or more channels 440.

Returning to FIG. 4A, the third dielectric wall 430 is disposed between the second epi layer 226 and the seventh epi layer 246. The third dielectric wall 430 is also disposed between the fourth epi layer 228 and the eighth epi layer 248. The third dielectric wall 430 also extends between the second gate 464 and the gate 244. In this case, a backside bridge is not used to couple the second gate 464 and the gate 244 since these gates are intended to be separate.

FIG. 4B shows a cross-sectional view taken along cross-section line Y1-Y2 in FIG. 4A, which intersects the second epi layer 226, the seventh epi layer 246, and the third dielectric wall 430. As shown in FIG. 4B, the third dielectric wall 430 is disposed between the second epi layer 226 and the seventh epi layer 246 to provide isolation between the second epi layer 226 and the seventh epi layer 246. The isolation prevents the second epi layer 226 and the seventh epi layer 246 from shorting, which allows the second diffusion region 218 and the fourth diffusion region 242 to be spaced closer together. The reduced spacing between the second diffusion region 218 and the fourth diffusion region 242 helps scale down the height of the cell 210 by allowing the bottom boundary of the cell 210 to be moved closer to the second diffusion region 218.

In this example, a first side 432 of the third dielectric wall 430 abuts the second epi layer 226 and a second side 434 of the third dielectric wall 430 abuts the seventh epi layer 246, in which the first side 432 and the second side 434 are opposite sides of the third dielectric wall 430. As shown in FIG. 4B, the third dielectric wall 430 extends in the z direction between the second epi layer 226 and the seventh epi layer 246. It is to be appreciated that the third dielectric wall 430 is not limited to the depth shown in the example in FIG. 4B.

In the example shown in FIG. 4B, the seventh epi layer 246 is coupled to one or more channels 450 discussed above (shown in FIG. 4C). In FIG. 4B, the one or more channels 450 are shown in dashed line to indicate the position of the one or more channels 450 in the z direction and the y direction. Note that the cross-section line Y1-Y2 does not intersect the one or more channels 450.

FIG. 4C shows a cross-sectional view taken along cross-section line Y3-Y4 in FIG. 4A. As shown in FIG. 4C, the one or more channels 270 pass through the first gate 462 and each of the one or more channels 270 is surrounded by the first gate 462 on four sides. The one or more channels 275 pass through the second gate 464 and each of the one or more channels 275 is surrounded by the second gate 464 on four sides. In this example, the first gate 462 abuts the first side 412 of the first dielectric wall 410 and the second gate 464 abuts the second side 414 of the first dielectric wall 410.

The one or more channels 440 pass through the gate 234 and each of the one or more channels 440 is surrounded by the gate 234 on four sides. In this example, the gate 234 abuts the first side 422 of the second dielectric wall 420 and the first gate 462 abuts the second side 424 of the second dielectric wall 420. The one or more channels 450 pass through the gate 244 and each of the one or more channels 450 is surrounded by the gate 244 on four sides. In this example, the second gate 464 abuts the first side 432 of the third dielectric wall 430 and the gate 244 abuts the second side 434 of the third dielectric wall 430.

Note that the epi layers 222, 226, 236, and 246 are not intersected by the cross-section line Y3-Y4 in this example. In FIG. 4C, each of the epi layers 222, 226, 236, and 246 is shown in dashed line to indicate the position of the epi layer in the z direction and the y direction.

Each of the one or more channels 270, 275, 440, and 450 may include a respective nanosheet extending in the x direction, a respective nanowire extending in the x direction, a respective fin extending in the x direction, or the like. It is to be appreciated that the one or more channels 270, 275, 440, and 450 are not limited to the exemplary cross-sectional shapes shown in the example in FIG. 4C, and may have other shapes in other implementations. In the example shown in FIG. 4C, each of the one or more channels 270, 275, 440, and 450 includes three channels. However, it is to be appreciated that each of the one or more channels 270, 275, 440, and 450 may include another number of channels in other implementations.

As shown in FIG. 4C, the first dielectric wall 410 separates the first gate 462 and the second gate 464. To retain electrical continuity between the first gate 462 and the second gate 464, the backside bridge 470 couples the first gate 462 and the second gate 464. As shown in FIG. 4C, the backside bridge 470 extends in the y direction underneath the first gate 462, the second gate 464, and the portion of the first dielectric wall 410 between the gates 462 and 464. In this example, the backside bridge 470 is coupled to a backside (i.e., back surface) of the first gate 462 and a backside (i.e., back surface) of the second gate 464, and crosses under the first dielectric wall 410 to couple the first gate 462 and the second gate 464. The backside bridge 470 may include metal (e.g., the same metal used for the backside contacts 252 and 256 or another metal).

As shown in FIG. 4C, the second dielectric wall 420 separates the gate 234 and the first gate 462. In this case, the gate 234 and the first gate 462 are intended to be separate (i.e., transistors 230 and 212 do not share a gate in this example). Because the gate 234 and the first gate 462 are intended to be separate, a backside bridge is not needed to couple the gate 234 and the first gate 462.

As shown in FIG. 4C, the third dielectric wall 430 separates the gate 244 and the second gate 464. In this case, the gate 244 and the second gate 464 are intended to be separate (i.e., transistors 240 and 214 do not share a gate in this example). Because the gate 244 and the second gate 464 are intended to be separate, a backside bridge is not needed to couple the gate 244 and the second gate 464.

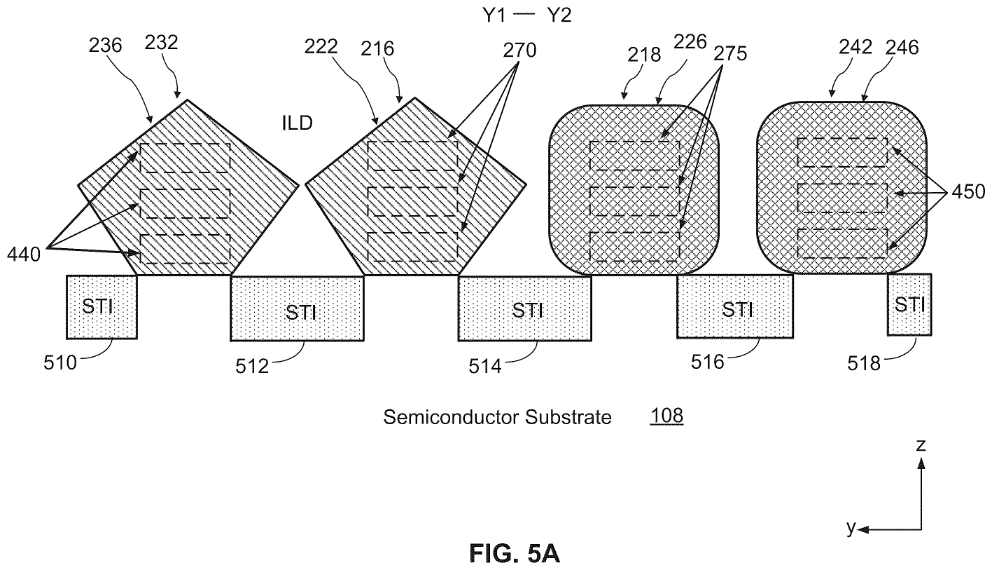

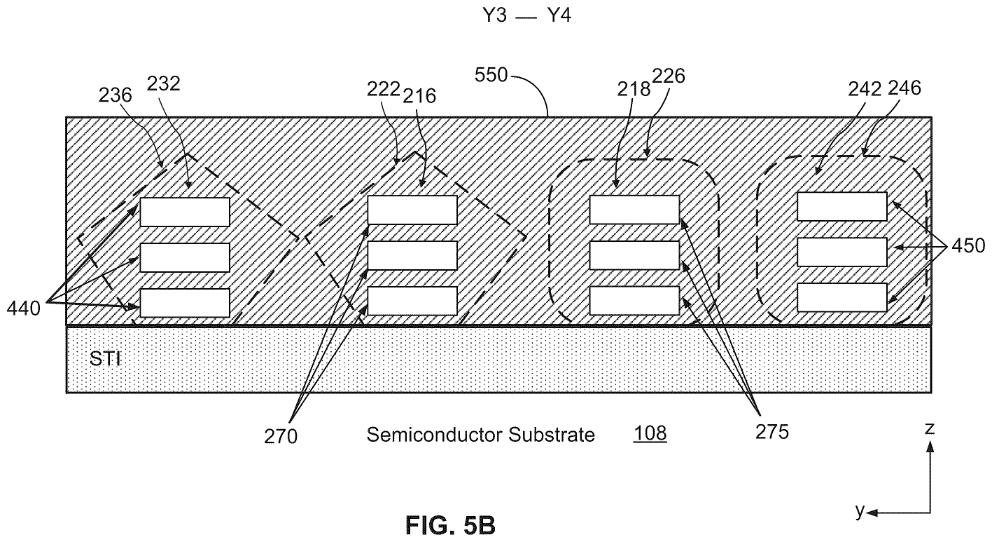

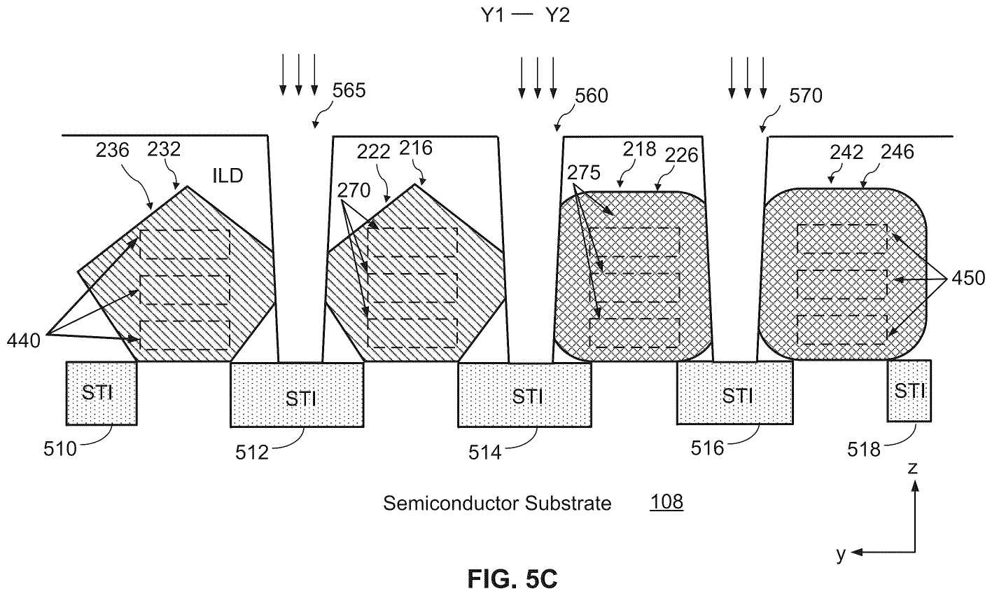

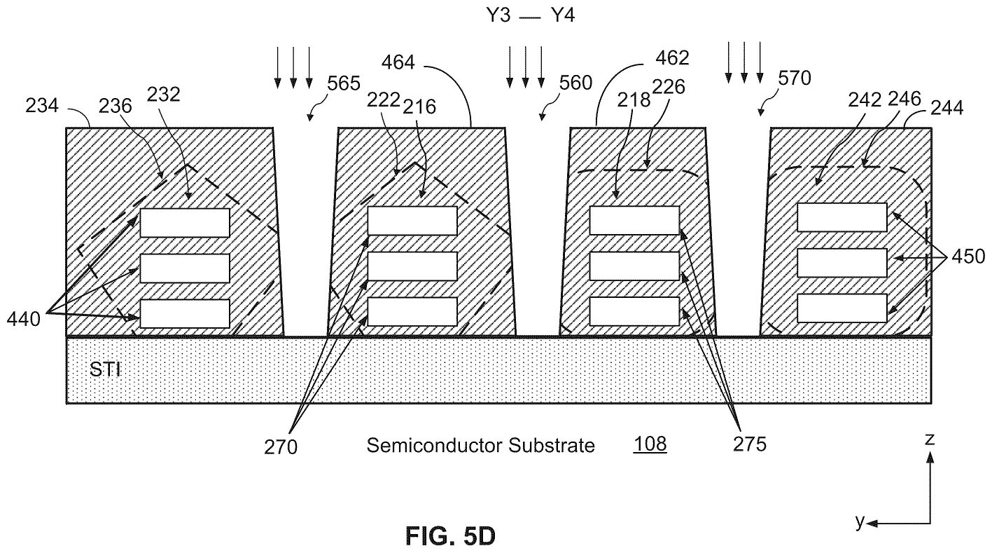

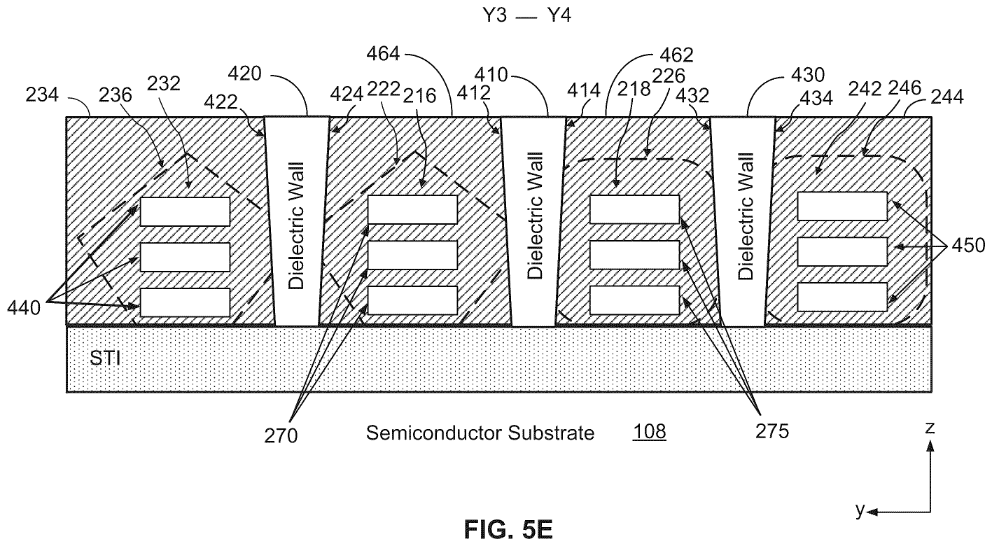

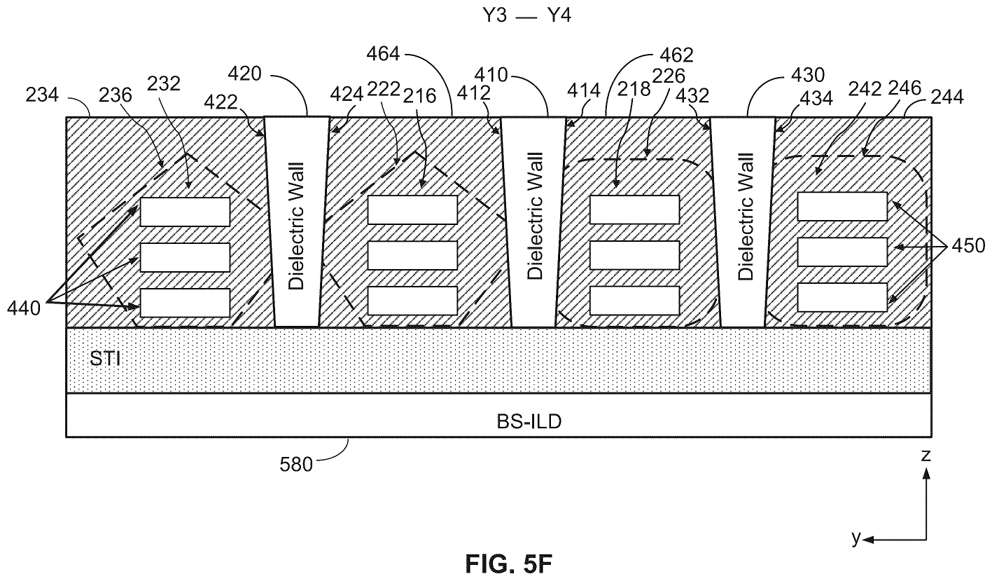

An exemplary process flow for fabricating the dielectric walls 410, 420, and 430 and the backside bridge 470 will now be described according to certain aspects with reference to FIGS. 5A to 5F. As discussed further below, the dielectric walls 410, 420, and 430 are formed during frontside processing and the backside bridge 470 is formed during backside processing according to certain aspects.

FIG. 5A shows a cross-sectional view taken along cross-section line Y1-Y2 of the epi layers 222, 226, 236, and 246 before formation of the dielectric walls 410, 420, and 430. The epi layers 222, 226, 236, and 246 may be formed using an epi growth process and/or epi deposition process. FIG. 5A also shows an example of shallow trench isolation (STI) regions 510, 512, 514, 516, and 518, which may be formed in the semiconductor substrate 108. In some implementations, the STI regions 510, 512, 514, 516, and 518 may be omitted. In the example shown in FIG. 5A, the space (i.e., gaps) between the epi layers 222, 224, 226, 228, 236, 238, 246, and 248 may be filled with an interlayer dielectric (ILD).

It is to be appreciated that the epi layers 222, 226, 236, and 246 may be spaced closer together than shown in the example in FIG. 5A. For example, in some cases, the adjacent tips of the first epi layer 222 and the fifth epi layer 236 may touch. In this example, the second dielectric wall 420 (which is formed later) will isolate the first epi layer 222 and the fifth epi layer 236 to prevent shorting of the first epi layer 222 and the fifth epi layer 236.

FIG. 5B shows a cross-sectional view taken along cross-section line Y3-Y4 at the same stage of chip fabrication as FIG. 5A. FIG. 5B shows an example of a contiguous gate 550 extending in the y direction. As discussed further below, the gate 550 shown in FIG. 5B is later cut into the gates 462, 464, 234, and 244 shown in FIG. 4C. At this stage in fabrication, each of the one or more channels 270, 275, 440, and 450 passes through the gate 550.

FIG. 5C shows a cross-sectional view taken along cross-section line Y1-Y2 in which a first trench 560 is etched between the epi layers 222 and 226, a second trench 565 is etched between the epi layers 222 and 236, and a third trench 570 is etched between the epi layers 226 and 246. The trenches 560, 565, and 570 are etched from the frontside. The areas of the chip 100 that are etched to form the trenches 560, 565, and 570 may be selected using a lithographic process and/or another technique.

The etching process may include a reactive ion etching process, a plasma etching process, and/or another type of suitable etching process. In FIG. 5C, the direction of the etching is indicated by the arrows pointing into the openings of the trenches 560, 565, and 570. As shown in FIG. 5C, the etching process etches through the ILD between the epi layers 222, 226, 236, and 246 to form the trenches 560, 565, and 570. The etching process may also etch through (i.e., cut through) portions of the epi layers 222, 224, 236, and 246, as discussed further below.

In the example in FIG. 5C, the first trench 560 is between the first epi layer 222 and the second epi layer 226, and cuts through a portion of the first epi layer 222 and a portion of the second epi layer 226. In cases where the adjacent sides of the first epi layer 222 and the second epi layer 226 touch before the frontside etching to form the first trench 560, the frontside etching etches away the portions of the epi layers 222 and 226 that are touching, thereby isolating the epi layers 222 and 226. The first trench 560 may also extend in the x direction between the third epi layer 224 and the fourth epi layer 228 (not shown in FIG. 5C).

The second trench 565 is between the first epi layer 222 and the fifth epi layer 236, and cuts through a portion of the first epi layer 222 and a portion of the fifth epi layer 236. In cases where the adjacent sides of the first epi layer 222 and the fifth epi layer 236 touch before the frontside etching to form the second trench 565, the frontside etching etches away the portions of the epi layers 222 and 236 that are touching, thereby isolating the epi layers 222 and 236. The second trench 565 may also extend in the x direction between the sixth epi layer 238 and the third epi layer 224 (not shown in FIG. 5C).

The third trench 570 is between the second epi layer 226 and the seventh epi layer 246, and cuts through a portion of the second epi layer 226 and a portion of the seventh epi layer 246. In cases where the adjacent sides of the second epi layer 226 and the seventh epi layer 246 touch before the frontside etching to form the third trench 570, the frontside etching etches away the portions of the epi layers 226 and 246 that are touching, thereby isolating the epi layers 226 and 246. The third trench 570 may also extend in the x direction between the fourth epi layer 228 and the eighth epi layer 248 (not shown in FIG. 5C).

Thus, in this example, the trenches 560, 565, and 570 for the dielectric walls 410, 420, and 430 are etched after formation of the epi layers 222, 224, 236, and 246 (e.g., the trenches 560, 565, and 570 are etched after (i.e., post) the epi growth and/or epi deposition process). This allows the epi layers 222, 224, 236, and 246 to be moved closer together and even touch before the trenches 560, 565, and 570 are etched, which provides further cell height reduction. In this example, the epi layers 222, 224, 236, and 246 are allowed to touch during the epi growth and/or epi deposition process for further cell height reduction since the epi layers 222, 224, 236, and 246 are subsequently separated (i.e., isolated) by the trenches 560, 565, and 570, which cut through the portions of the epi layers 222, 224, 236, and 246 that are touching.

FIG. 5D shows a cross-sectional view taken along cross-section line Y3-Y4 at the same stage of chip fabrication as FIG. 5C. As shown in FIG. 5D, the trenches 560, 565, and 570 cut the gate 550 shown in FIG. 5B into the gates 462, 464, 234, and 244. In this example, each cut may also be referred to as full cut which fully cuts the gate 550 in the z direction. In this example, each of the trenches 560, 565, and 570 extends in the x direction and cuts both the gate 550 and adjacent epi layers (e.g., adjacent epi layers 222 and 226). In this regard, each of the trenches 560, 565, and 570 may also be referred to as an extended cut since the trench extends in the x direction. In certain aspects, each of the trenches 560, 565, and 570 may extend the entire length of the cell 210 in the x direction (e.g., as shown in the example in FIG. 4A). However, it is to be appreciated that the present disclosure is not limited to this example.

After formation of the trenches 560, 565, 570, the first trench 560, the second trench 565, and the third trench 570 are filled with dielectric material to form the first dielectric wall 410, the second dielectric wall 420, and the third dielectric wall 430, respectively, as shown in FIG. 5E, which is taken along cross-section line Y3-Y4. The dielectric material may include one or more of the following: silicon dioxide (SiO2), silicon nitride (Si3N4), silicon carbon oxynitride (SiCON), etc.

After formation of the dielectric walls 410, 420, and 430, the topside layers 105 (shown in FIGS. 1D and 1E) are deposited and patterned to provide signal routing and/or power distribution for the transistors 212, 214, 230, and 240 and other transistors integrated in the chip 100.

After the frontside processing discussed above, a carrier wafer (not shown) may be bonded to the top of the chip 100 for structural support. The chip 100 may be flipped to expose the backside of the semiconductor substrate 108, and most or all of the semiconductor substrate 108 (e.g., silicon substrate) may be removed. For example, the semiconductor substrate 108 may be removed using a combination of backside grinding, chemical mechanical polishing (CMP), and/or etching.

FIG. 5F shows a cross-sectional view of the dielectric walls 410, 420, and 430 and the gates 462, 464, 234, and 244 after removal of most or all of the semiconductor substrate 108. In this example, a thin backside interlayer dielectric (BS-ILD) 580 is formed on the backside of the chip 100.

After formation of the BS-ILD 580, the backside bridge 470 shown in FIG. 4C may be formed. For example, the backside bridge 470 may be formed by etching away a portion of the BS-ILD 580 and STI under the gates 462 and 464 and the first dielectric wall 410 to form an opening exposing back surfaces of the gates 462 and 464. The opening may then be filled with a metal to form the backside bridge 470. For process efficiency, the backside bridge 470 may be formed using the same patterning and metallization process used to form the backside contacts 252 and 256 (shown in FIG. 4B). In other words, formation of the backside bridge 470 may be integrated into the backside contact process flow. In this example, the backside bridge 470 may include the same backside metal used for the backside contacts 252 and 256. However, it is to be appreciated that the present disclosure is not limited to this example.

After formation of the backside bridge 470 and the backside contacts 252 and 256, the backside metal layer BM0 may be formed and patterned to form backside rails (e.g., backside rails 250 and 254). In addition, the remaining backside metal layers (e.g., backside layers 155) may be formed and patterned (e.g., to form one or more backside power distribution networks).

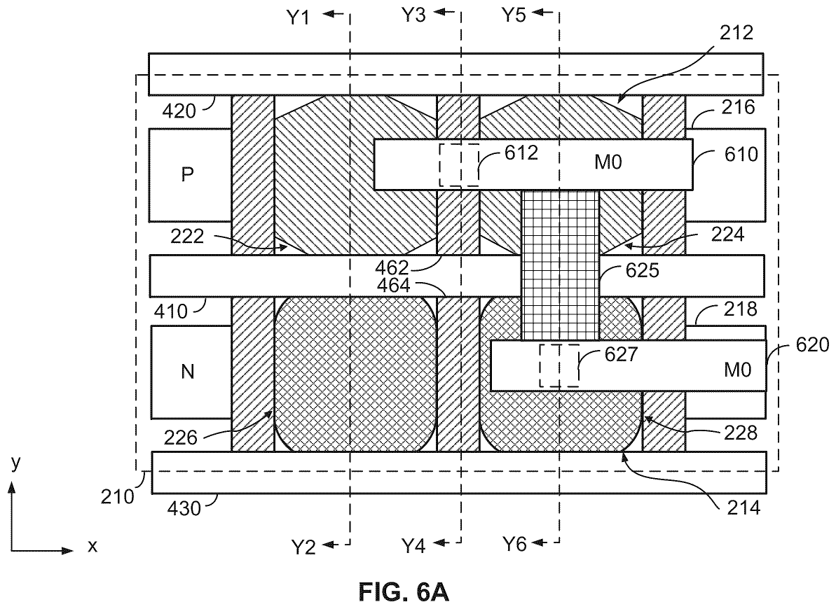

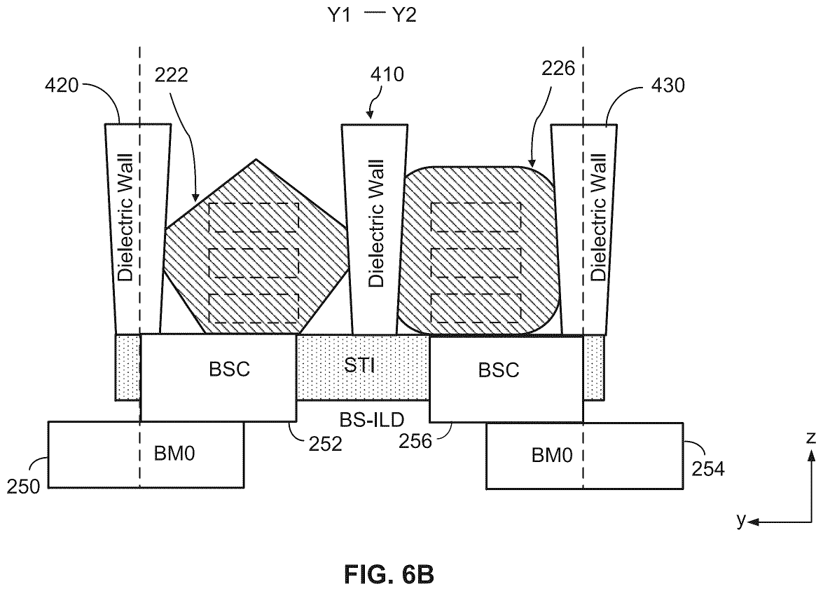

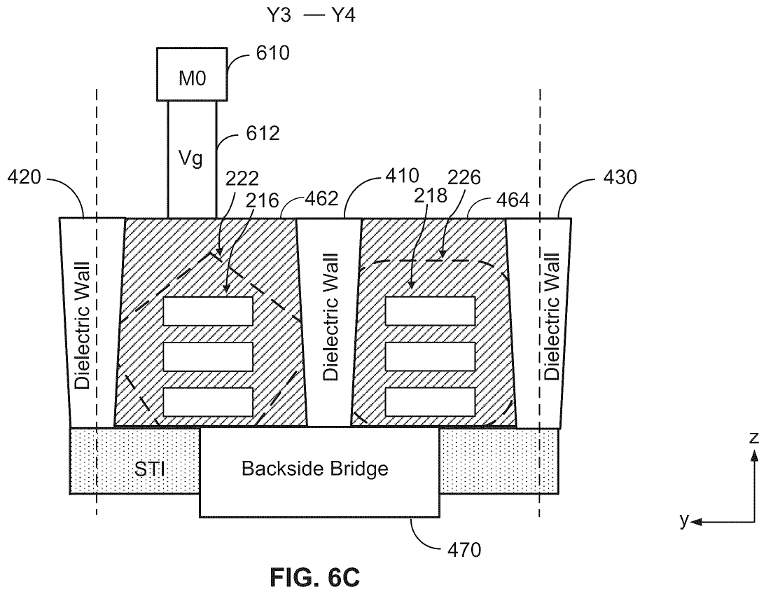

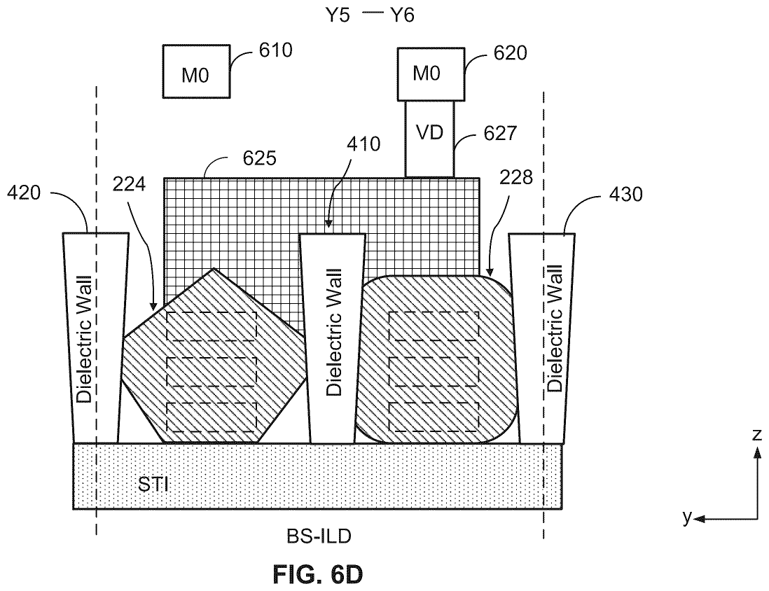

FIG. 6A shows a top view of exemplary signal routing for the cell 210 according to certain aspects. In this example, the signal routing may couple the first transistor 212 and the second transistor 214 to form a complementary inverter. However, it is to be appreciated that the present disclosure is not limited to this example.

In the example in FIG. 6A, the signal routing includes a first metal routing 610 extending in the x direction and a second metal routing 620 extending in the x direction and spaced apart from the first metal routing 610 in the y direction. The first metal routing 610 and the second metal routing 620 are both formed from metal layer M0.

The signal routing also includes a via 612 coupling the first metal routing 610 to the first gate 462. The via 612 is disposed between the first gate 462 and the first metal routing 610 in the z direction. In FIG. 6A, the via 612 is shown in dashed line to indicate that the via 612 is underneath the first metal routing 610. The first gate 462 is coupled to the second gate 464 through the backside bridge 470 (shown in FIG. 6C) to provide a shared gate for the transistors 212 and 214. Thus, in this example, the first metal routing 610 is coupled to the first gate 462 and the second gate 464 through the via 612 and the backside bridge 470. In this example, the first metal routing 610 may provide an input to the inverter.

The signal routing also includes a topside contact 625 (e.g., topside contact 124 formed from MD or CA contact layer) and a via 627 (e.g., via 134). The contact 625 extends in the y direction and is disposed on the topside of the third epi layer 224 and the topside of the fourth epi layer 228. The via 627 couples the contact 625 to the second metal routing 620 and is disposed between the contact 625 and the second metal routing 620 in the z direction. The via 627 is shown in dashed line to indicate that the via 627 is underneath the second metal routing 620. Thus, in this example, the second metal routing 620 is coupled to the third epi layer 224 and the fourth epi layer 228 through the via 627 and the contact 625. In this example, the second metal routing 620 may provide an output to the inverter.

FIG. 6B shows a cross-sectional view of the cell 210 taken along cross-section line Y1-Y2 in FIG. 6A. In FIG. 6B, the vertical dashed lines indicate the boundary of the cell 210. In this example, the first epi layer 222 is coupled to the first rail 250 by the first backside contact 252, and the second epi layer 226 is coupled to the second rail 254 by the second backside contact 256. The first rail 250 may be a supply rail coupling the first epi layer 222 to a supply voltage, and the second rail 254 may be a ground rail coupling the second epi layer 226 to ground. Although not shown in FIG. 6B, it is to be appreciated that backside contacts 252 and 256 may be coupled to the rails 250 and 254, respectively, by vias (e.g., BVD in FIG. 1D). In this example, the first dielectric wall 410 isolates the first epi layer 222 from the second epi layer 226, which prevents a short between the first rail 250 (e.g., supply rail) and the second rail 254 (e.g., ground rail) in this example.

FIG. 6C shows a cross-sectional view of the cell 210 taken along cross-section line Y3-Y4 in FIG. 6A. As shown in FIG. 6C, the via 612 couples the first metal routing 610 to the first gate 462. The first gate 462 is coupled to the second gate 464 through the backside bridge 470 to provide a shared gate for the transistors 212 and 214.

FIG. 6D shows a cross-sectional view of the cell 210 taken along cross-section line Y5-Y6 in FIG. 6A. As shown in FIG. 6D, the via 627 couples the second metal routing 620 to the contact 625. The contact 625 extends in the y direction and passes over the first dielectric wall 410 to couple the third epi layer 224 and the fourth epi layer 22 to the via 627.

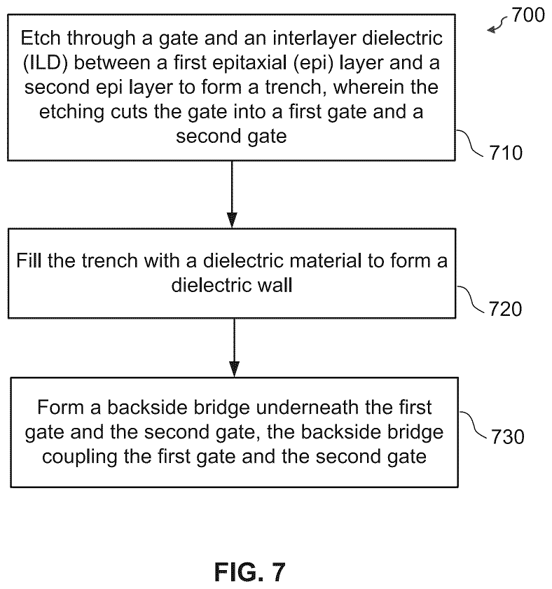

FIG. 7 shows an exemplary method 700 of chip fabrication according to certain aspects of the present disclosure.

At block 710, a gate and an interlayer dielectric (ILD) between a first epitaxial (epi) layer and a second epi layer are etched through to form a first trench, wherein the etching cuts the gate into a first gate and a second gate. The gate may correspond to the gate 220, the first gate may correspond to the first gate 462, the second gate may correspond to the second gate 464, the first epi layer may correspond to the first epi layer 222, the second epi layer may correspond to the second epi layer 226, and the trench may correspond to the first trench 560.

At block 720, the trench is filled with a dielectric material to form a dielectric wall. For example, the dielectric material may include at least one of silicon dioxide (SiO2), silicon nitride (Si3N4), and silicon carbon oxynitride (SiCON).

At block 730, a backside bridge is formed underneath the first gate and the second gate, the backside bridge coupling the first gate and the second gate. The backside bridge may correspond to the backside bridge 470.

In certain aspects, the etching includes etching away a portion of the first epi layer and a portion of the second epi layer. For example, the portion of the first epi layer and the portion of the second epi layer may touch.

The method 700 may also include forming multiple topside metal layers above the first epi layer, the second epi layer, and the dielectric wall, and removing most or all of a semiconductor substrate of the chip after forming the multiple topside metal layers. For example, the topside metal layers may correspond to the topside metal layers 140, and the semiconductor substrate may correspond to the semiconductor substrate 108 (e.g., silicon substrate). Removing most or all of the semiconductor substrate may include backside grinding and chemical mechanical polishing (CMP). As used herein, “most or all” means at least 90 percent.

In certain aspects, forming the backside bridge comprises forming the backside bridge after removing most or all of the semiconductor substrate.

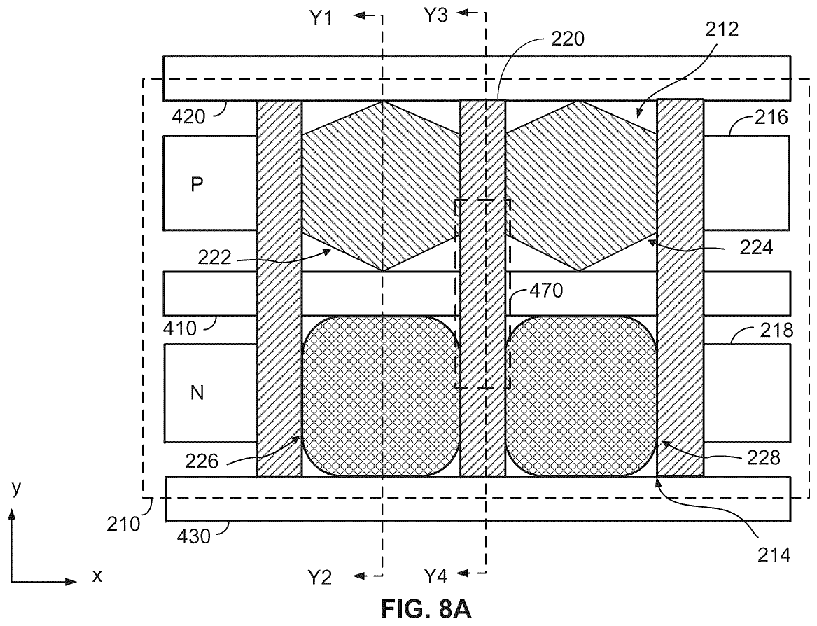

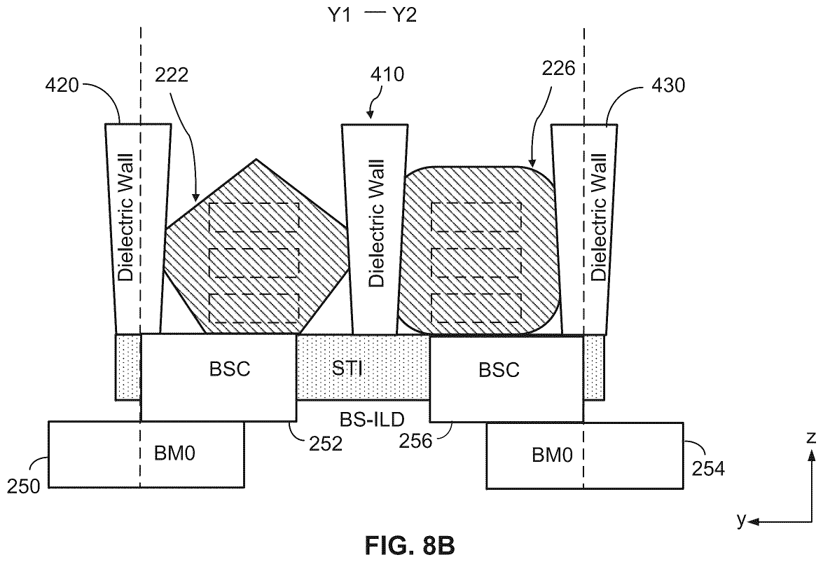

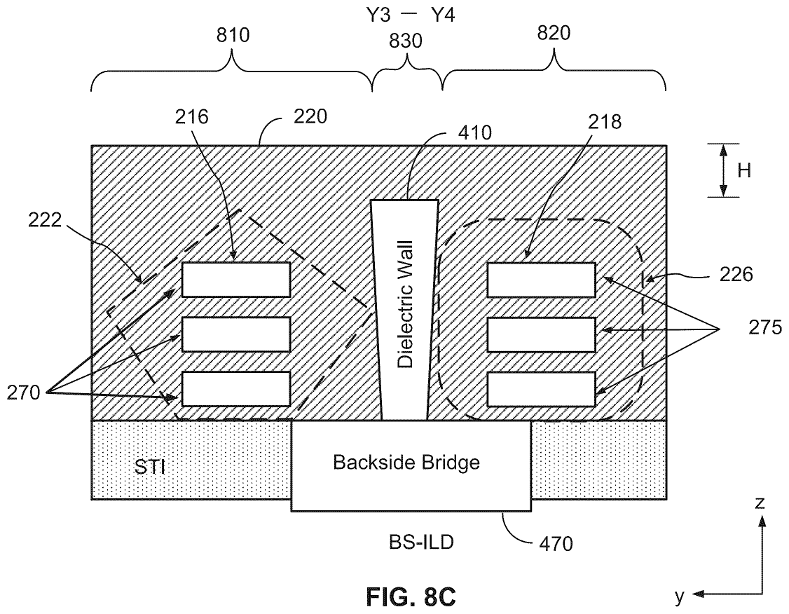

It is to be appreciated that the backside bridge 470 is not limited to a full gate cut and that the backside bridge 470 may be used in other examples in which the first dielectric wall 410 passes through the shared gate 220. In this regard, FIG. 8A shows a top view of an example in which the first dielectric wall 410 passes through the gate 220, which is shared by the first transistor 212 and the second transistor 214 in this example.

In this example, the dielectric walls 410, 420, 430 may be formed after formation of the epi layers 222, 224, 226, 228, 236, 238, 246, and 248 and before the formation of the gate 220 (e.g., using a replacement metal gate process), as discussed further below. Note that cpi layers 236, 238, 246, and 248 are not shown in FIG. 8A.

In this example, the backside bridge 470 extends in the y direction underneath the gate 220 and the first dielectric wall 410. As discussed further below, the backside bridge 470 reduces the gate resistance in the area where the first dielectric wall 410 passes through gate 220. The backside bridge 470 is shown in dashed line in FIG. 8A to indicate that the backside bridge 470 is underneath the gate 220 and the first dielectric wall 410.

FIG. 8B shows a cross-sectional view taken along cross-section line Y1-Y2 in FIG. 8A, which intersects the first epi layer 222, the second epi layer 226, and the first dielectric wall 410. As shown in FIG. 8B, the first dielectric wall 410 is disposed between the first epi layer 222 and the second epi layer 226 to provide isolation between the first epi layer 222 and the second epi layer 226.

FIG. 8C shows a cross-sectional view taken along cross-section line Y3-Y4 in FIG. 8A. As shown in FIG. 8C, the one or more channels 270 and the one or more channels 275 pass through the gate 220. Each of the one or more channels 270 may be surrounded by the gate 220 on four sides and each of the one or more channels 275 may be surrounded by the gate 220 on four sides. However, it is to be appreciated that the present disclosure is not limited to this example. For example, for a finFET process, each of the one or more channels 270 and each of the one or more channels 275 may be orientated vertically and surrounded by the gate 220 on three sides.

In this example, the first dielectric wall 410 passes through the gate 220, in which the first dielectric wall 410 is disposed between a first portion 810 of the gate 220 and a second portion 820 of the gate 220, and a third portion 830 of the gate 220 extends over the gate 220. In this example, the third portion 830 of the gate 220 extending over the first dielectric wall 410 increases the resistance between the first portion 810 and the second portion 820 of the gate 220. This is because the gate 220 narrows in the third portion 830, as shown in FIG. 8C. The resistance between the first portion 810 and the second portion 820 of the gate 220 may be reduced by increasing the height H of the gate 220 over the dielectric wall 410 in the z direction. However, this increases the size of the transistors 212 and 214 in the z direction.

The backside bridge 470 overcomes this by providing a conductive path between the first portion 810 and the second portion 820 of the gate 220, which reduces the resistance between the first portion 810 and the second portion 820 of the gate 220 without having to raise the height of the gate 220. As shown in FIG. 8C, the backside bridge 470 extends in the y direction underneath the first portion 810 of the gate 220, the second portion 820 of the gate 220, and the first dielectric wall 410. In this example, the backside bridge 470 is coupled to a backside (i.e., back surface) of the first portion 810 of the gate 220 and a backside (i.e., back surface) of the second portion 820 of the gate 220, and crosses under the first dielectric wall 410. Thus, the backside bridge 470 is coupled between the first portion 810 of the gate 220 and the second portion 820 of the gate 220. As discussed above, the backside bridge 470 may be formed during backside processing and may include metal (e.g., the same metal used for the backside contacts 252 and 256 or another metal). In certain aspects, the backside bridge 470 allows the height of the gate 220 to be reduced while maintaining electrical continuity between the first portion 810 of the gate 220 and the second portion 820 of the gate 220.

In this example, the first dielectric wall 410 may be formed after formation of the epi layers 222, 224, 226, 228, 236, 238, 246, and 248 but before formation of the gate 220 using a replacement metal gate process. In this example, the chip 100 may include a sacrificial gate (a polysilicon gate) before formation of the gate 220, in which the first dielectric wall 410 is formed while the sacrificial gate is present. After the first dielectric wall 410 is formed, the sacrificial gate is removed and replaced with a metal gate material (e.g., high-k metal gate (HKMG) material) to form the gate 220. This allows a portion of the gate 220 to extends over the dielectric wall 410, as shown in FIG. 8C.

Implementation examples are described in the following numbered clauses:

1. A chip, comprising:
one or more first channels extending in a first direction;
a first epitaxial (epi) layer coupled to the one or more first channels;
a first gate, wherein the one or more first channels pass through the first gate;
one or more second channels extending in the first direction;
a second epi layer coupled to the one or more second channels;
a second gate, wherein the one or more second channels pass through the second gate;
a dielectric wall extending in the first direction, wherein the dielectric wall is disposed between the first epi layer and the second epi layer, and the dielectric wall is disposed between the first gate and the second gate; and
a backside bridge underneath the first gate and the second gate, wherein the backside bridge couples the first gate and the second gate.

2. The chip of clause 1, wherein the backside bridge comprises metal.

3. The chip of clause 1 or 2, wherein the backside bridge is coupled to a back surface of the first gate and a back surface of the second gate, and the backside bridge crosses underneath a portion of the dielectric wall between the first gate and the second gate.

4. The chip of any one of clauses 1 to 3, wherein the first epi layer abuts a first side of the dielectric wall, and the second epi layer abuts a second side of the dielectric wall.

5. The chip of clause 4, wherein the first gate abuts the first side of the dielectric wall, and the second gate abuts the second side of the dielectric wall.

6. The chip of any one of clauses 1 to 5, wherein each of the first gate and the second gate extends in a second direction perpendicular to the first direction.

7. The chip of clause 6, wherein the backside bridge extends in the second direction underneath the first gate and the second gate.

8. The chip of any one of clauses 1 to 7, further comprising:
a third epi layer coupled to the one or more first channels, wherein the first gate is between the first epi layer and the third epi layer; and
a fourth epi layer coupled to the one or more second channels, wherein the second gate is between the second epi layer and the fourth epi layer, and the dielectric wall is disposed between the third epi layer and the fourth epi layer.

9. The chip of clause 8, wherein the backside bridge is coupled to a back surface of the first gate and a back surface of the second gate, and the backside bridge crosses underneath a portion of the dielectric wall between the first gate and the second gate.

10. The chip of clause 8 or 9, further comprising a topside contact disposed on the third epi layer and the fourth epi layer, wherein the topside contact passes over the dielectric wall between the third epi layer and the fourth epi layer.

11. The chip of clause 10, further comprising:
a metal routing formed from a topside metal layer; and
a vias coupling the topside contact to the metal routing.

12. The chip of any one of clauses 1 to 11, further comprising:
a first backside contact coupled to a back surface of the first epi layer; and
a second backside contact coupled to a back surface of the second epi layer.

13. The chip of clause 12, further comprising:
a first rail formed from a backside metal layer, wherein the first rail is coupled to the first backside contact; and
a second rail formed from the backside metal layer, wherein the second rail is coupled to the second backside contact.

14. The chip of clause 13, wherein the first rail is a supply rail and the second rail is a ground rail.

15. The chip of any one of clauses 1 to 14, wherein the dielectric wall comprises at least one of silicon dioxide (SiO2), silicon nitride (Si3N4), and silicon carbon oxynitride (SiCON).

16. A method of chip fabrication, comprising:
etching through a gate and an interlayer dielectric (ILD) between a first epitaxial (epi) layer and a second epi layer to form a trench, wherein the etching cuts the gate into a first gate and a second gate;
filling the trench with a dielectric material to form a dielectric wall; and
forming a backside bridge underneath the first gate and the second gate, the backside bridge coupling the first gate and the second gate.

17. The method of clause 16, wherein the etching includes etching away a portion of the first epi layer and a portion of the second epi layer.

18. The method of clause 16 or 17, wherein the first epi layer, the second epi layer, and the dielectric wall are formed on a semiconductor substrate, and the method further comprises:
forming multiple topside metal layers above the first epi layer, the second epi layer, and the dielectric wall; and
removing most or all of the semiconductor substrate after forming the multiple topside metal layers.

19. The method of clause 18, wherein forming the backside bridge comprises forming the backside bridge after removing most or all of the semiconductor substrate.

20. The method of any one of clauses 16 to 19, wherein the dielectric material comprises at least one of silicon dioxide (SiO2), silicon nitride (Si3N4), and silicon carbon oxynitride (SiCON).

21. A chip, comprising:
one or more first channels extending in a first direction;
a first epitaxial (epi) layer coupled to the one or more first channels;
one or more second channels extending in the first direction;
a second epi layer coupled to the one or more second channels;
a gate extending in a second direction perpendicular to the first direction, wherein the one or more first channels and the one or more second channels pass through the gate;
a dielectric wall extending in the first direction, wherein the dielectric wall is disposed between the first epi layer and the second epi layer, the dielectric wall is disposed between a first portion of the gate and a second portion of the gate, and a third portion of the gate passes over the dielectric wall; and
a backside bridge extending in the second direction underneath the first portion of the gate, the second portion of the gate, and the dielectric wall, wherein the backside bridge is coupled between the first portion of the gate and the second portion of the gate.

22. The chip of clause 21, wherein the backside bridge comprises metal.

23. The chip of clause 21 or 22, wherein the backside bridge is coupled to a back surface of the first portion of the gate and a back surface of the second portion of the gate, and the backside bridge crosses underneath a portion of the dielectric wall between the first portion of the gate and the second portion of the gate.

Within the present disclosure, the word “exemplary” is used to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect electrical coupling between two structures. As used herein, the term “approximately” means within 90 percent to 110 percent of the stated value.

Any reference to an element herein using a designation such as “first,” “second,” and so forth does not generally limit the quantity or order of those elements. Rather, these designations are used herein as a convenient way of distinguishing between two or more elements or instances of an element. Thus, a reference to first and second elements does not mean that only two elements can be employed, or that the first element must precede the second element.

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples described herein but is to be accorded the widest scope consistent with the principles and novel features disclosed herein.

What is claimed is:

1. A chip, comprising:
one or more first channels extending in a first direction;
a first epitaxial (epi) layer coupled to the one or more first channels;
a first gate, wherein the one or more first channels pass through the first gate;
one or more second channels extending in the first direction;
a second epi layer coupled to the one or more second channels;
a second gate, wherein the one or more second channels pass through the second gate;
a dielectric wall extending in the first direction, wherein the dielectric wall is disposed between the first epi layer and the second epi layer, and the dielectric wall is disposed between the first gate and the second gate; and
a backside bridge underneath the first gate and the second gate, wherein the backside bridge couples the first gate and the second gate.

2. The chip of claim 1, wherein the backside bridge comprises metal.

3. The chip of claim 1, wherein the backside bridge is coupled to a back surface of the first gate and a back surface of the second gate, and the backside bridge crosses underneath a portion of the dielectric wall between the first gate and the second gate.

4. The chip of claim 1, wherein the first epi layer abuts a first side of the dielectric wall, and the second epi layer abuts a second side of the dielectric wall.

5. The chip of claim 4, wherein the first gate abuts the first side of the dielectric wall, and the second gate abuts the second side of the dielectric wall.

6. The chip of claim 1, wherein each of the first gate and the second gate extends in a second direction perpendicular to the first direction.

7. The chip of claim 6, wherein the backside bridge extends in the second direction underneath the first gate and the second gate.

8. The chip of claim 1, further comprising:
a third epi layer coupled to the one or more first channels, wherein the first gate is between the first epi layer and the third epi layer; and
a fourth epi layer coupled to the one or more second channels, wherein the second gate is between the second epi layer and the fourth epi layer, and the dielectric wall is disposed between the third epi layer and the fourth epi layer.

9. The chip of claim 8, wherein the backside bridge is coupled to a back surface of the first gate and a back surface of the second gate, and the backside bridge crosses underneath a portion of the dielectric wall between the first gate and the second gate.

10. The chip of claim 8, further comprising a topside contact disposed on the third epi layer and the fourth epi layer, wherein the topside contact passes over the dielectric wall between the third epi layer and the fourth epi layer.

11. The chip of claim 10, further comprising:
a metal routing formed from a topside metal layer; and
a vias coupling the topside contact to the metal routing.

12. The chip of claim 1, further comprising:
a first backside contact coupled to a back surface of the first epi layer; and
a second backside contact coupled to a back surface of the second epi layer.

13. The chip of claim 12, further comprising:
a first rail formed from a backside metal layer, wherein the first rail is coupled to the first backside contact; and
a second rail formed from the backside metal layer, wherein the second rail is coupled to the second backside contact.

14. The chip of claim 13, wherein the first rail is a supply rail and the second rail is a ground rail.

15. A method of chip fabrication, comprising:
etching through a gate and an interlayer dielectric (ILD) between a first epitaxial (epi) layer and a second epi layer to form a trench, wherein the etching cuts the gate into a first gate and a second gate;
filling the trench with a dielectric material to form a dielectric wall; and
forming a backside bridge underneath the first gate and the second gate, the backside bridge coupling the first gate and the second gate.

16. The method of claim 15, wherein the etching includes etching away a portion of the first epi layer and a portion of the second epi layer.

17. The method of claim 15, wherein the first epi layer, the second epi layer, and the dielectric wall are formed on a semiconductor substrate, and the method further comprises:
forming multiple topside metal layers above the first epi layer, the second epi layer, and the dielectric wall; and
removing most or all of the semiconductor substrate after forming the multiple topside metal layers.

18. The method of claim 17, wherein forming the backside bridge comprises forming the backside bridge after removing most or all of the semiconductor substrate.

19. A chip, comprising:
one or more first channels extending in a first direction;
a first epitaxial (epi) layer coupled to the one or more first channels;
one or more second channels extending in the first direction;
a second epi layer coupled to the one or more second channels;
a gate extending in a second direction perpendicular to the first direction, wherein the one or more first channels and the one or more second channels pass through the gate;
a dielectric wall extending in the first direction, wherein the dielectric wall is disposed between the first epi layer and the second epi layer, the dielectric wall is disposed between a first portion of the gate and a second portion of the gate, and a third portion of the gate passes over the dielectric wall; and
a backside bridge extending in the second direction underneath the first portion of the gate, the second portion of the gate, and the dielectric wall, wherein the backside bridge is coupled between the first portion of the gate and the second portion of the gate.

20. The chip of claim 19, wherein the backside bridge is coupled to a back surface of the first portion of the gate and a back surface of the second portion of the gate, and the backside bridge crosses underneath a portion of the dielectric wall between the first portion of the gate and the second portion of the gate.
